(19) United States
(12) Patent Application Publication
(10) Pub. No.: US 2026/0136854 A1
(43) Pub. Date: May 14, 2026

(54) PROCESSING METHOD AND SEMICONDUCTOR DEVICE MANUFACTURING METHOD

(71) Applicant: CANON KABUSHIKI KAISHA, Tokyo (JP)

(72) Inventors: TETSUYA KIMURA, Tokyo (JP); KOSUKE ASANO, Kanagawa (JP); HIROSHI KUROSAWA, Chiba (JP)

(21) Appl. No.: 19/380,708

(22) Filed: Nov. 5, 2025

(30) Foreign Application Priority Data
Nov. 14, 2024 (JP) 2024-199201

(51) Int. Cl. H01L 21/02; H01L 21/3105

(52) U.S. Cl. CPC H10P 14/6536; H10P 95/062

(57) ABSTRACT

A method of processing a substrate having a first surface with an outer peripheral portion lower than a central portion and forming a second surface flatter than the first surface is provided. The method includes forming a planarization film on at least the outer peripheral portion by placing a curable composition on the substrate, bringing a superstrate into contact with the curable composition, and curing the curable composition, and executing CMP before or after the forming. The second surface is formed through the forming and the executing the CMP.

### BACKGROUND

### Field of the Technology

The present disclosure relates to a processing method and a semiconductor device manufacturing method.

### Description of the Related Art

In manufacturing a semiconductor device, a damascene process can be used to form a wiring pattern using a metal such as copper. In a damascene process, after a metal film is formed so as to fill a trench formed in an interlayer dielectric film with a metal, a portion of the metal film which covers the interlayer dielectric film is removed in a chemical mechanical polishing (CMP) step. At this time, an outside portion of the interlayer dielectric film is more easily polished than a central portion, and the flatness of the upper surface of the interlayer dielectric film can deteriorate.

Alternatively, in manufacturing a semiconductor device, after a photoresist film is formed on a substrate for a photolithography process, in order to prevent contamination and the like on a substrate cassette, the photoresist film on an outer peripheral portion of the substrate, a film under the photoresist film, and the like can be removed by etching. Such a process is called an edge bead removal (EBR) process. Once an EBR process is performed, a portion having undergone the EBR process and a region inside the portion can be inclined and subjected to a deterioration in flatness due to a subsequent planarization step or the like. This is because, in the subsequent process, a pattern formation defect can occur or a junction defect can occur in a case where the substrate is joined to another substrate.

### SUMMARY

The present disclosure provides a technique advantageous in reducing problems caused by a deterioration in flatness on an outer peripheral portion of a substrate or its neighboring portion.

The present disclosure includes a processing method of processing a substrate having a first surface with an outer peripheral portion lower than a central portion and forming a second surface flatter than the first surface, the method comprising: forming a planarization film on at least the outer peripheral portion by placing a curable composition on the substrate, bringing a superstrate into contact with the curable composition, and curing the curable composition; and executing CMP before or after the forming, wherein the second surface is formed through the forming and the executing the CMP.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a view showing one arrangement example of a planarization apparatus;

FIGS. 2A and 2B are views showing an arrangement example of a substrate;

FIGS. 3A to 3E are schematic sectional views exemplarily showing processing methods according to the first and second embodiments;

FIGS. 4A to 4C are schematic sectional views exemplarily showing a processing method according to the first embodiment;

FIGS. 5A to 5C are schematic sectional views exemplarily showing a processing method according to the second embodiment;

FIGS. 6A to 6C are schematic sectional views exemplarily showing a processing method according to the third embodiment;

FIGS. 7A to 7D are schematic sectional views exemplarily showing the processing method according to the third embodiment;

FIGS. 8A to 8D are schematic sectional views exemplarily showing processing methods according to the fourth and fifth embodiments;

FIGS. 9A to 9C are schematic sectional views exemplarily showing the processing method according to the fourth embodiment;

FIGS. 10A to 10C are schematic sectional views exemplarily showing the processing method according to the fifth embodiment;

FIGS. 11A to 11D are schematic sectional views exemplarily showing processing methods according to the sixth and seventh embodiments;

FIGS. 12A to 12C are schematic sectional views exemplarily showing the processing method according to the sixth embodiment;

FIGS. 13A to 13C are schematic sectional views exemplarily showing the processing method according to the seventh embodiment;

FIGS. 14A to 14D are schematic sectional views exemplarily showing processing methods according to the eighth and ninth embodiments;

FIGS. 15A to 15C are schematic sectional views exemplarily showing the processing method according to the eighth embodiment;

FIGS. 16A to 16C are schematic sectional views exemplarily showing the processing method according to the ninth embodiment;

FIGS. 17A to 17C are schematic sectional views exemplarily showing processing methods according to the 10th and 11th embodiments;

FIGS. 18A to 18C are schematic sectional views exemplarily showing the processing method according to the 10th embodiment;

FIGS. 19A to 19C are schematic sectional views exemplarily showing the processing method according to the 11th embodiment;

FIGS. 20A to 20D are schematic sectional views exemplarily showing a processing method according to the 12th embodiment;

FIGS. 21A to 21C are schematic sectional views exemplarily showing the processing method according to the 12th embodiment;

FIGS. 22A to 22C are schematic sectional views exemplarily showing a processing method according to the 13th embodiment;

FIGS. 23A and 23B are schematic sectional views exemplarily showing the processing method according to the 13th embodiment;

FIGS. 24A to 24C are schematic sectional views exemplarily showing a processing method according to the 14th embodiment;

FIGS. 25A to 25C are schematic sectional views exemplarily showing the processing method according to the 14th embodiment;

FIGS. 26A and 26B are views exemplarily showing the height distribution of a surface of a substrate after a CMP step;

FIG. 27 is a view exemplarily showing the array of a plurality of shot regions on a substrate; and

FIGS. 28A to 28C are schematic sectional views exemplarily showing a processing method according to a modification of the seventh embodiment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

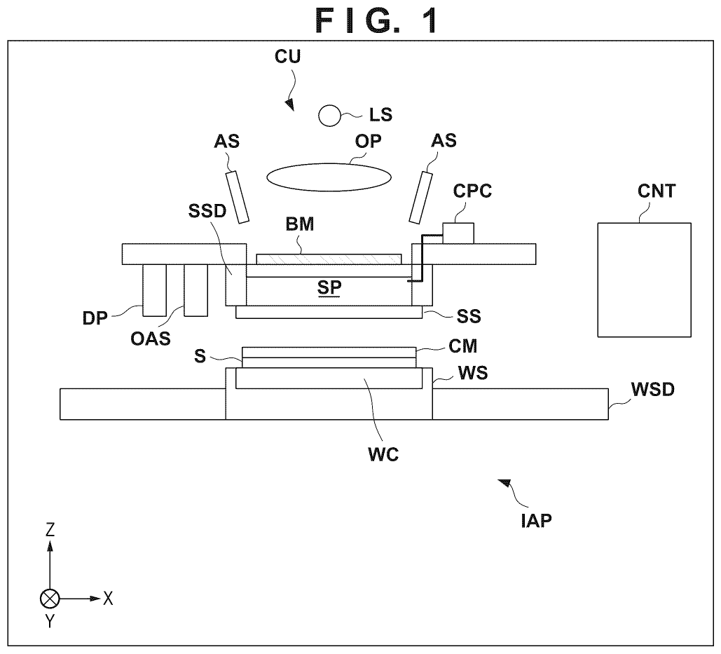

The processing method described below includes a film forming step of forming a planarization film by placing a curable composition on a substrate, bringing a superstrate into contact with the curable composition, and curing the curable composition. An arrangement example of a film forming apparatus IAP for forming a planarization film will be described first. FIG. 1 schematically shows one arrangement example of the planarization apparatus IAP that can be used to form a planarization film in a film forming step. The film forming apparatus IAP forms a planarization film by using an inkjet adaptive planarization (IAP) technique. More specifically, the planarization apparatus IAP forms a planarization film on a substrate S by using a superstrate SS as a mold having a flat surface. The planarization apparatus IAP can form a planarization film by placing a curable composition CM on the substrate S, bringing the superstrate SS into contact with the curable composition CM, and curing the curable composition CM.

As the curable composition CM, a composition (to be also referred to as a resin in an uncured state) to be cured by receiving curing energy is used. As the curing energy, an electromagnetic wave, heat, or the like is used. The electromagnetic wave is light selected from the wavelength range of 10 nm (inclusive) to 1 mm (inclusive), for example, infrared light, a visible light beam, ultraviolet light, or the like. The curable composition CM may be understood as a composition cured by light irradiation or a composition cured by heating. Among these, a photo-curable composition cured by light contains at least a polymerizable compound and a photopolymerization initiator, and may contain a nonpolymerizable compound or a solvent, as needed. The nonpolymerizable compound is at least one material selected from the group consisting of a sensitizer, a hydrogen donor, an internal mold release agent, a surfactant, an antioxidant, and a polymer component. The curable composition CM may be applied, onto the substrate, in a droplet shape or in an island or film shape formed by connecting a plurality of droplets using a liquid injection head. Alternatively, the curable composition CM may be placed, onto the substrate, in a film shape by a spin coater or a slit coater. The viscosity (the viscosity at 25° C.) of the curable composition CM is, for example, 1 mPa·s (inclusive) to 100 mPa·s (inclusive).

The planarization apparatus IAP can include a substrate stage WS including a substrate chuck WC that holds the substrate S, and a substrate driving mechanism WSD that drives the substrate stage WS. The planarization apparatus IAP can also include a superstrate driving mechanism SSD that holds and drives the superstrate SS. The substrate driving mechanism WSD and the superstrate driving mechanism SSD constitute a relative driving mechanism that drives at least one of the substrate S and the superstrate SS to adjust the relative position between the substrate S and the superstrate SS. Adjustment of the relative position by the relative driving mechanism includes driving for bringing the superstrate SS into contact with the curable composition CM on the substrate S and driving for separating the superstrate SS from the cured product of the curable composition CM. Adjustment of the relative position by the relative driving mechanism also includes alignment between the substrate S and the superstrate SS. The substrate driving mechanism WSD can be configured to drive the substrate S with respect to a plurality of axes (for example, three axes including the X-axis, Y-axis, and θZ-axis, and preferably six axes including the X-axis, Y-axis, Z-axis, θX-axis, θY-axis, and θZ-axis). The superstrate driving mechanism SSD can be configured to drive the superstrate SS with respect to a plurality of axes (for example, three axes including the Z-axis, θX-axis, and θY-axis, and preferably six axes including the X-axis, Y-axis, Z-axis, θX-axis, θY-axis, and θZ-axis). The planarization apparatus IAP can include a pressure controller CPC that controls the three-dimensional shape of the superstrate SS by adjusting the pressure in a sealed space SP formed on the back surface of the superstrate SS. It is possible to deform the superstrate into a downward convex shape or planarize it by adjusting the pressure in the sealed space SP by the pressure controller CPC.

The planarization apparatus IAP can include one or a plurality of alignment scopes AS for measuring the alignment error between the substrate S and the superstrate SS. The planarization apparatus IAP can include a curing unit CU that forms a planarization film by curing the curable composition CM by applying curing energy to the curable composition CM via the superstrate SS. The curing unit CU can include a light source LS that generates light as curing energy and an optical system OP that irradiates the curable composition CM on the substrate S with light from the light source LS. The curing unit CU may also include an adjusting unit BM for adjusting a light irradiation region so as to irradiate a predetermined portion of the curable composition CM on the substrate S (a portion located at a peripheral portion of the substrate) with light (curing energy). The adjusting unit BM can include a light-shielding member placed at a position shifted from an imaging plane of the optical system OP (or a plane conjugate to the imaging plane). The distance between the imaging plane of the optical system OP (or the plane conjugate to the imaging plane) and the light-shielding member can be determined so as to adjust the intensity distribution of light applied to the curable composition CM on the substrate S by the curing unit CU. Increasing this distance can increase the width of a change portion between a maximum light intensity portion and a minimum light intensity portion on the imaging plane of the optical system OP. In contrast to this, reducing the distance can reduce the width of the change portion between the maximum light intensity portion and the minimum light intensity portion. The adjusting unit BM may include, for example, a digital mirror device (DMD) that controls the irradiation region or irradiation intensity distribution of light (curing energy). The irradiation intensity distribution can be adjusted by time-divisionally controlling the respective mirrors constituting the DMD. The DMD can be placed on a plane conjugate to the imaging plane of the optical system OP.

The planarization apparatus IAP can include a dispenser DP that applies or arranges the curable composition CM onto the substrate S. The planarization apparatus IAP can include an off-axis scope OAS for detecting the position of the alignment mark of the substrate S. The planarization apparatus IAP can include a control unit CNT that controls the respective components of the planarization apparatus IAP. The control unit CNT is an information processing apparatus that can be formed from, for example, a PLD (the abbreviation of Programmable Logic Device) such as an FPGA (the abbreviation of Field Programmable Gate Array), an ASIC (the abbreviation of Application Specific Integrated Circuit), a computer incorporating a program, or a combination of some or all of these.

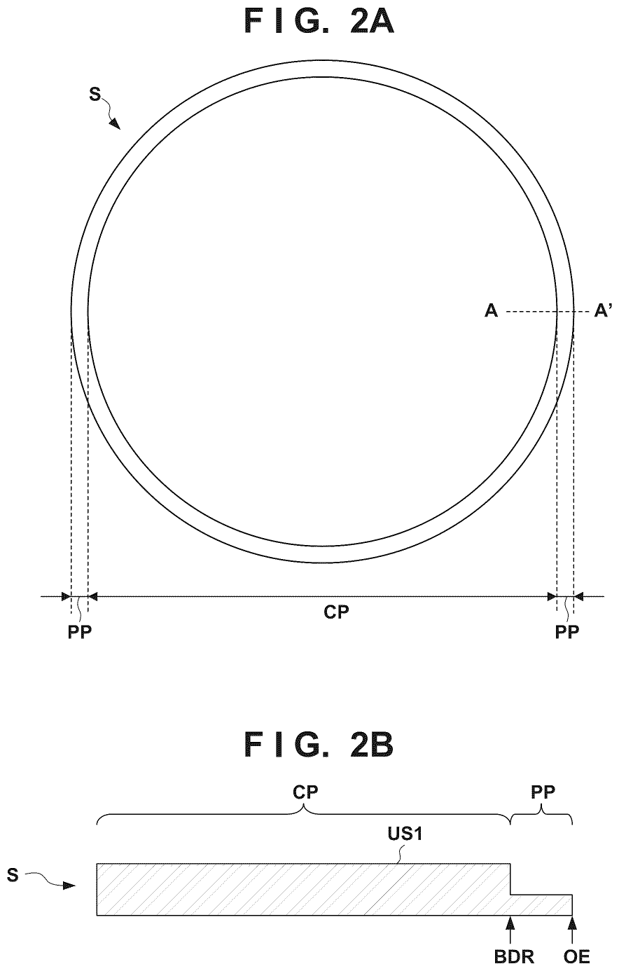

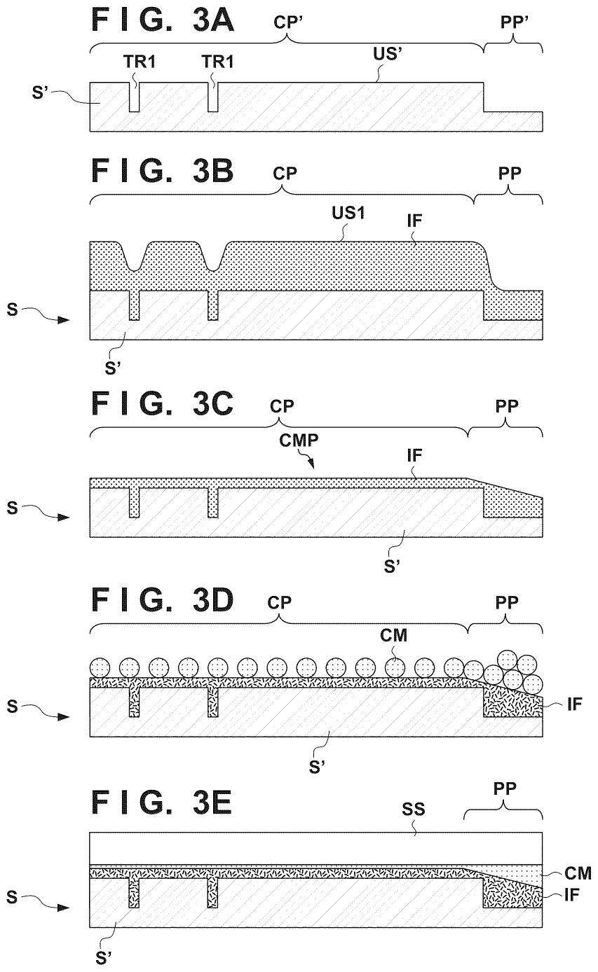

FIGS. 2A and 2B schematically show the arrangement of the substrate S. FIG. 2A is a schematic plan view of a surface of the substrate S when viewed from its normal direction. FIG. 2B is a schematic sectional view taken along line A - A′ in FIG. 2A. The substrate S can have a first surface US1 with an outer peripheral portion PP lower than a central portion CP. The outer peripheral portion PP may be a portion having undergone an EBR process or include a portion having undergone an EBR process. Alternatively, the outer peripheral portion PP may be a beveled portion. The distance between a boundary BDR between the outer peripheral portion PP and the central portion CP and an outer edge OE can be, for example, a distance falling within the range of 3 mm to 5 mm. In the example shown in FIG. 2B, although there is a distinct stepped portion between the central portion CP and the outer peripheral portion PP, the outer peripheral portion PP may be a portion that gradually decreases in height from the boundary BDR to the outer edge OE. The first surface US1 can be formed of, for example, any one of an insulator, an interlayer dielectric film, or a semiconductor substrate. Note that the sectional views shown in FIGS. 3A to 19 each are a schematic sectional view taken along line A - A′ in FIG. 2A.

A processing method according to the present embodiment can form a second surface US2 flatter than the first surface US1 by processing the substrate S having the first surface with the outer peripheral portion PP lower than the central portion CP. The processing method according to the present embodiment can include a film forming step of forming a planarization film on at least the outer peripheral portion PP by placing a curable composition on the substrate S, bringing a superstrate into contact with the curable composition, and curing the curable composition. The processing method according to the present embodiment can also include a CMP step executed before or after a film forming step. The second surface US2 can be formed on the substrate S through the film forming step and the CMP step. The second surface US2 flatter than the first surface US1 means that, for example, the maximum height difference of the second surface is smaller than that of the first surface.

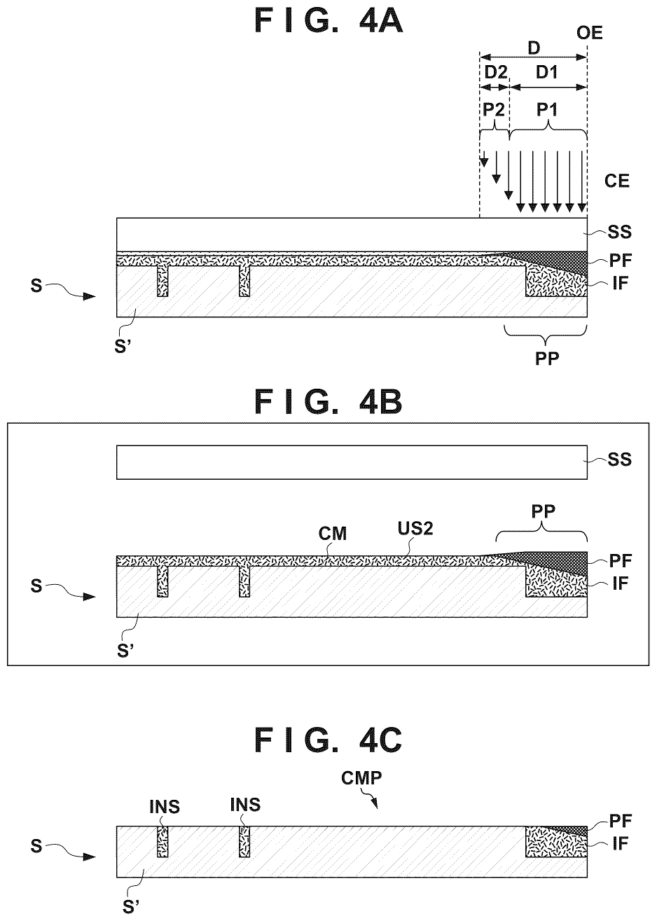

The processing method according to the first embodiment will be exemplarily described below with reference to FIGS. 3A to 3E and 4C. A preparation step of preparing the substrate S having the first surface US1 with the outer peripheral portion PP lower than the central portion CP will be described first with reference to FIGS. 3A and 3B. Unless explicitly specified otherwise, a preparation step is not an essential step in the processing method according to the present disclosure, and the substrate S having the first surface US1 with the outer peripheral portion PP lower than the central portion CP may be provided as a target object for which the processing method according to the present disclosure is executed.

In the step shown in FIG. 3A, a semiconductor substrate S′ having an initial first surface US′ with an initial outer peripheral portion PP′ lower than an initial central portion CP′ can be prepared. The central portion CP′ of the semiconductor substrate S′ can have one or a plurality of trenches TR1. In the step shown in FIG. 3B, an insulating film IF can be formed on the surface US′ of the semiconductor substrate S′. The insulating film IF can be formed so as to fill the trench TR1 with an insulator. The insulating film IF can be formed from, for example, silicon oxide, silicon nitride, or silicon oxynitride. With the steps shown in FIGS. 3A and 3B, the substrate S having the first surface US1 with the outer peripheral portion PP lower than the central portion CP is prepared. In this example, the first surface US1 is formed of the insulating film IF placed in the trench TR1 provided in the semiconductor substrate S′ and on the surface of the semiconductor substrate S′.

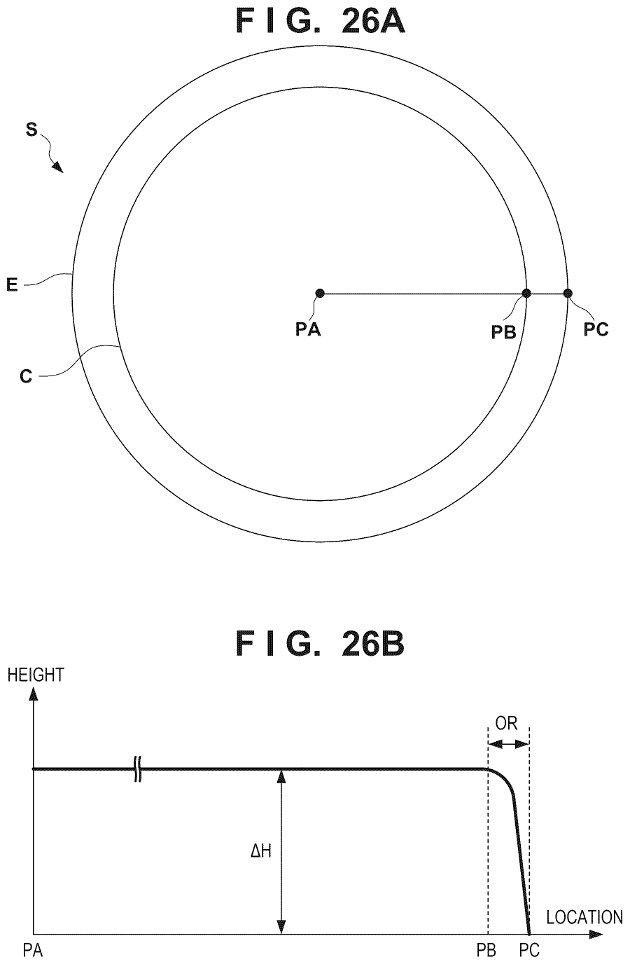

A film forming step and a CMP step will be described below. In the first embodiment, the CMP step is executed before the film forming step. FIG. 3C schematically shows the CMP step. In the CMP step, the insulating film IF is polished. In the CMP step, although the surface of the insulating film IF can be properly planarized at the central portion CP of the substrate S, the surface of the insulating film IF is not planarized at the outer peripheral portion PP of the substrate S. Consequently, an inclined surface that is inclined toward an outer edge of the substrate S can be formed. FIGS. 26A and 26B exemplarily show the height distribution of the surface of the substrate S after the execution of a CMP step with respect to the insulating film IF. Reference symbols PA, PB, and PC respectively denote the center of the substrate S, an inner edge position of the inclined surface, and an outer edge position of the substrate S. On the substrate S having a diameter of 300 mm, PC—PB can be, for example, about 3 mm to 5 mm. Reference symbol ΔH denotes the height difference of the inclined surface and can be, for example, about 3 μm to 5 μm. In a state in which an inclined surface is formed on the outer peripheral portion PP, as a subsequent stacking step proceeds, the start position of the inclination on the layer forming the outermost surface gradually moves to the inward of the substrate S. This can cause a problem in a lithography step (patterning step). For this reason, in the first embodiment, a film forming step can be executed after a CMP step.

A film forming step executed after a CMP step will be described below with reference to FIGS. 3D, 3E, 4A, and 4B. The film forming apparatus IAP described above can be applied to the film forming step. In the film forming step, the planarization film PF is formed on at least the outer peripheral portion PP by placing the curable composition CM on the surface of the substrate S after the CMP step, bringing the superstrate SS into contact with the curable composition CM, and curing the curable composition CM. More specifically, first of all, in the step shown in FIG. 3D, the curable composition CM can be placed on the surface of the substrate S in the film forming apparatus IAP by using a dispenser DP. In this case, the curable composition CM can be placed in a droplet state on the surface of the substrate S. In the step shown in FIG. 3E, the superstrate SS is brought into contact with the curable composition CM placed on the surface of the substrate S, and the space between the surface of the substrate S and the superstrate SS is filled with the curable composition CM.

In the curing step shown in FIG. 4A, the curing unit CU cures the curable composition CM by irradiating the curable composition CM with curing energy CE. In this case, the adjusting unit BM can adjust an irradiation region so that the curing energy CE irradiates a portion (predetermined portion), of the curable composition CM on the surface of the substrate S, which is located on the outer peripheral portion PP. The adjusting unit BM can adjust the intensity distribution of the curing energy CE applied to the curable composition CM. More specifically, the adjusting unit BM irradiates a portion, of the curable composition CM on the surface of the substrate S, which extends from the outer edge OE of the substrate S by a predetermined distance D with the curing energy CE. The predetermined distance D may be larger than the width of the outer peripheral portion PP in the diametrical direction of the substrate S. Alternatively, the predetermined distance D may be smaller than the width of the outer peripheral portion PP in the diametrical direction of the substrate S. The predetermined distance D can be determined in accordance with the surface shape of the substrate S.

From another viewpoint, the adjusting unit BM can adjust the intensity distribution so as to irradiate a first portion P1, of the curable composition CM on the surface of the substrate S, which extends from the outer edge OE of the substrate S by a first distance D1 with the curing energy CE which has a first intensity. In addition, the adjusting unit BM can adjust the intensity distribution so as to irradiate a second portion P2, of the curable composition CM on the surface of the substrate S, which is placed adjacent to an inside of the first portion P1 with the curing energy CE such that the intensity gradually decreases from the first intensity to the second intensity toward the center of the substrate S. The second intensity is, for example, 0 or an intensity that substantially inhibits a curable composition from being cured (the same applies below). After the curing step, the first portion P1 of the curable composition CM on the surface of the substrate S is cured, and the second portion P2 gradually decreases in cure degree toward the center of the substrate S. Accordingly, the planarization film PF formed of the cured product of the curable composition CM can be formed on at least the outer peripheral portion PP of the substrate S.

In the step shown in FIG. 4B, the superstrate SS is separated from the planarization film PF and the curable composition CM in an uncured state. Thereafter, a removal step can be executed to remove the curable composition CM left after a curing step. The removal step can include, for example, a wet process of dissolving the curable composition CM. With the above film forming step, the planarization film PF is formed on at least the outer peripheral portion PP of the substrate S. With this step, the second surface US2 is formed by the planarization film PF and the exposed portion of the insulating film IF. The second surface US2 is a surface flatter than the first surface US1.

Subsequently, in the step shown in FIG. 4C, the unnecessary insulating film IF on the surface of the semiconductor substrate S′ is removed while the insulating film IF (an insulator INS) in the trench TR1 is left. This step can include a second CMP step. This makes it possible to obtain an STI structure having the trench TR1 filled with the insulator INS.

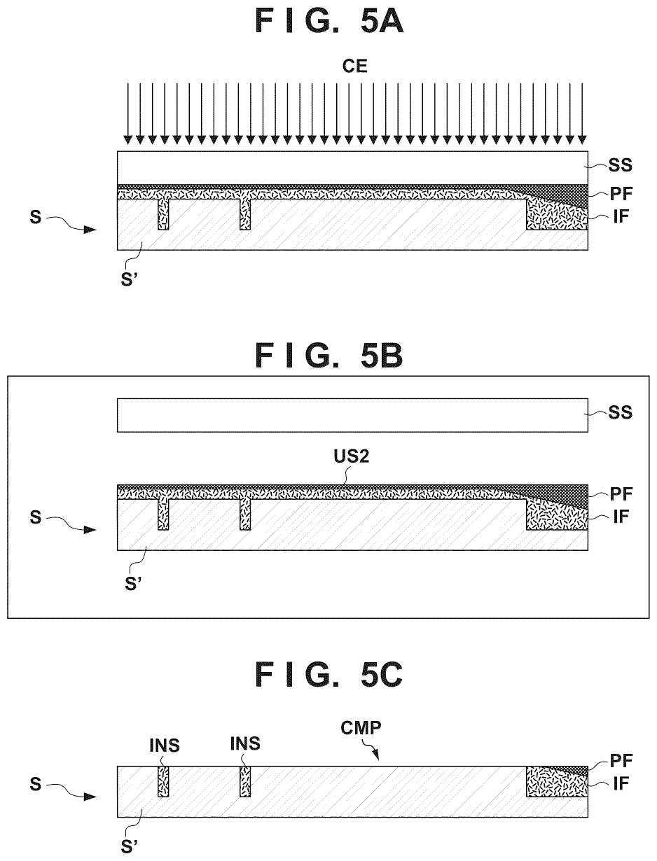

A processing method according to the second embodiment will be exemplarily described next with reference to FIGS. 3A to 3E and 5A to 5C. The second embodiment is a modification of the first embodiment. In a film forming step according to the second embodiment, a planarization film PF is formed on a central portion CP and an outer peripheral portion PP of a substrate S. From another viewpoint, an irradiation region of curing energy with respect to a curable composition CM in the second embodiment differs from that in the first embodiment in that curing energy CE can be applied to the curable composition CM on the central portion CP and the outer peripheral portion PP of the substrate S.

The steps shown in FIGS. 3A to 3E in the second embodiment may be the same as those in the first embodiment. In the second embodiment, after the step shown in FIG. 3E, in the curing step shown in FIG. 5A, a curing unit CU irradiates the curable composition CM on the central portion CP and the outer peripheral portion PP of the substrate S with the curing energy CE to cure the curable composition CM. In other words, in the second embodiment, in the curing step shown in FIG. 5A, the curing unit CU cures the entire curable composition CM by irradiating the entire curable composition CM on the substrate S with the curing energy CE. This changes the entire curable composition CM on the substrate S into the planarization film PF.

In the step shown in FIG. 5B, a superstrate SS is separated from the planarization film PF. This forms a second surface US2 using the planarization film PF. The second surface US2 is a surface flatter than a first surface US1. In the step shown in FIG. 5C, the unnecessary insulating film IF on the surface of the semiconductor substrate S′ is removed while an insulating film IF (an insulator INS) in a trench TR1 is left. This step can include, for example, the second CMP step. With this step, an STI structure with the trench TR1 filled with the insulator INS is obtained.

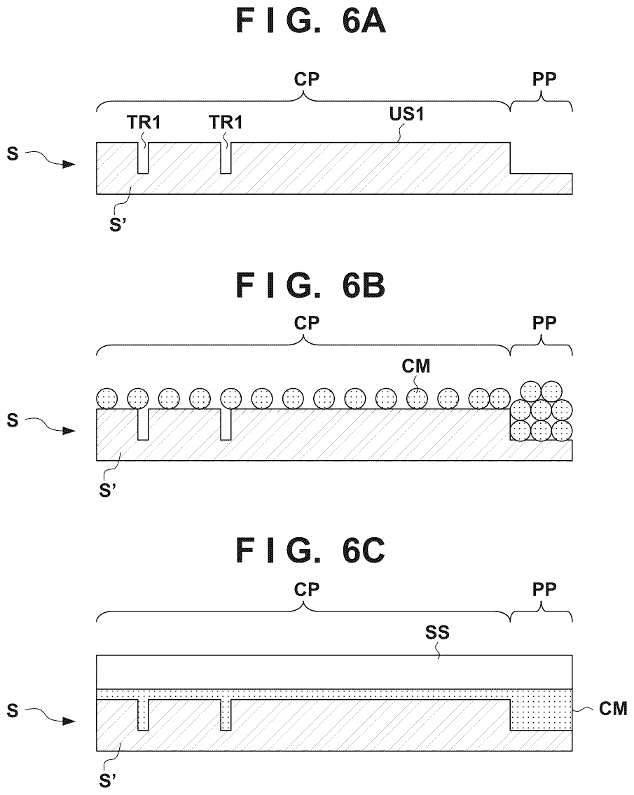

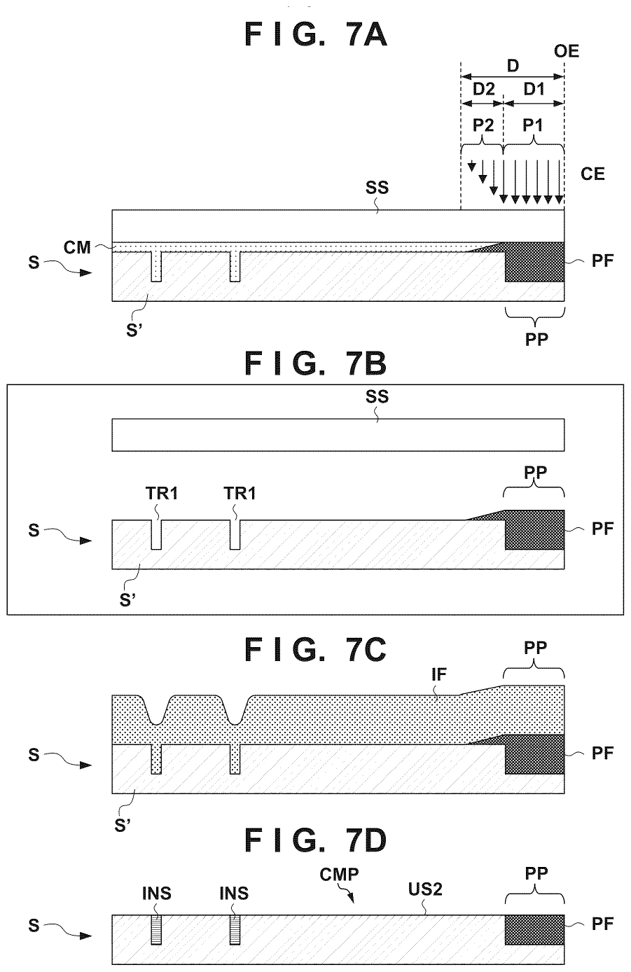

A processing method according to the third embodiment will be exemplarily described below with reference to FIGS. 6A to 6C and 7A to 7D. A substrate S having a first surface US1 with an outer peripheral portion PP lower than a central portion CP will be described with reference to FIG. 6A. The substrate S can have one or a plurality of trenches TR1 in the central portion CP. The substrate S can be formed of a semiconductor substrate S'. The first surface US1 can be formed of the semiconductor substrate S′. In other words, the first surface US1 can be a surface of the semiconductor substrate S′.

A film forming step and a CMP step will be described below. In the third embodiment, the CMP step is executed after the film forming step. The film forming step executed before the CMP step will be described with reference to FIGS. 6B, 6C, 7A, and 7B. The film forming apparatus IAP described above can be applied to the film forming step. In the film forming step, a planarization film PF is formed on at least the outer peripheral portion PP by placing a curable composition CM on the first surface US1 of the substrate S, bringing a superstrate SS into contact with the curable composition CM, and curing the curable composition CM. More specifically, first of all, in the step shown in FIG. 6B, the curable composition CM can be placed on the first surface US1 of the substrate S by using a dispenser DP in a film forming apparatus IAP. In this case, the curable composition CM can be placed in a droplet state on the first surface US1 of the substrate S. In the step shown in FIG. 6C, the superstrate SS is brought into contact with the curable composition CM placed on the first surface US1 of the substrate S, and the space between the first surface US1 of the substrate S and the superstrate SS is filled with the curable composition CM.

In the curing step shown in FIG. 7A, a curing unit CU cures the curable composition CM by irradiating the curable composition CM with curing energy CE. In this case, an adjusting unit BM can adjust an irradiation region so as to irradiate a portion (predetermined portion), of the curable composition CM on the first surface US1 of the substrate S, which is located on the outer peripheral portion PP with the curing energy CE. The adjusting unit BM can adjust the intensity distribution of the curing energy CE applied to the curable composition CM. More specifically, the adjusting unit BM irradiates, for example, a portion, of the curable composition CM on the first surface US1 of the substrate S, which extends from an outer edge OE of the substrate S by a predetermined distance D with the curing energy CE. The predetermined distance D may be larger than the width of the outer peripheral portion PP in the diametrical direction of the substrate S. Alternatively, the predetermined distance D may be smaller than the width of the outer peripheral portion PP in the diametrical direction of the substrate S. The predetermined distance D can be determined in accordance with the surface shape of the first surface US1 of the substrate S.

From another viewpoint, the adjusting unit BM can adjust the intensity distribution so as to irradiate a first portion P1, of the curable composition CM on the first surface US1 of the substrate S, which extends from the outer edge OE of the substrate S by a first distance D1 with the curing energy CE having a first intensity. In addition, the adjusting unit BM can adjust the intensity distribution of the curing energy CE so as to irradiate a second portion P2, of the curable composition CM on the first surface US1 of the substrate S, which is placed adjacent to an inside of the first portion P1 with the curing energy CE such that the intensity gradually decreases from the first intensity to the second intensity toward the center of the substrate S. After the curing step, the first portion P1 of the curable composition CM on the first surface US1 of the substrate S is cured, and the second portion P2 gradually decreases in cure degree toward the center of the substrate S. Accordingly, the planarization film PF formed of the cured product of the curable composition CM can be formed on at least the outer peripheral portion PP of the substrate S.

In the step shown in FIG. 7B, the superstrate SS is separated from the planarization film PF and the curable composition CM in an uncured state. Thereafter, a removal step can be executed to remove the curable composition CM left after a curing step. The removal step can include, for example, a wet process of dissolving the curable composition CM. The removal step is executed to expose the trench TR1 placed in the central portion CP. With the above film forming step, the planarization film PF is formed at least on the outer peripheral portion PP of the substrate S.

In the filling step shown in FIG. 7C, the insulating film IF can be formed on a surface US of the substrate S. An insulating film IF is formed so as to fill the trench TR1 with an insulator. The insulating film IF can be formed from, for example, silicon oxide, silicon nitride, or silicon oxynitride. In the CMP step shown in FIG. 7D, the unnecessary insulating film IF on the surface of the substrate S (the semiconductor substrate S') is polished while the insulating film IF (an insulator INS) in the trench TR1 is left. This can obtain an STI structure with the trench TR1 filled with the insulator INS. With this step, a second surface US2 is formed by a surface of the planarization film PF and a surface of the substrate S. The second surface US2 is a surface flatter than the first surface US1.

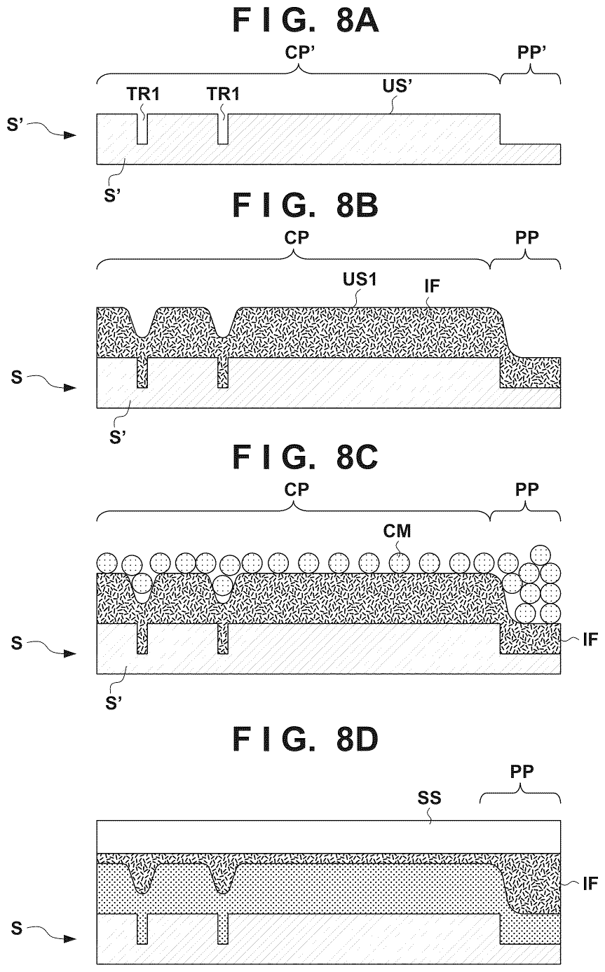

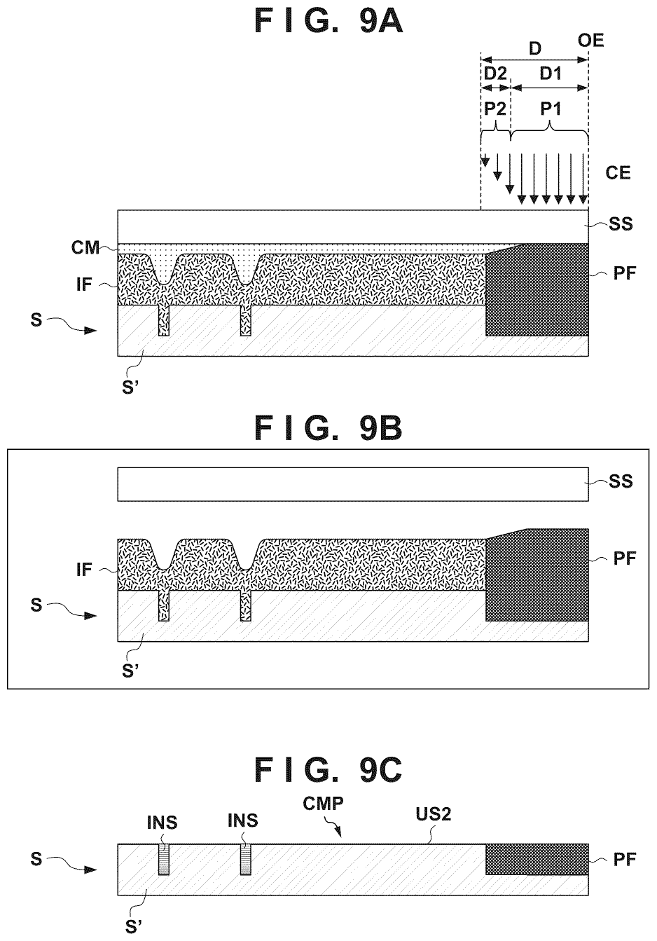

A processing method according to the fourth embodiment will be exemplarily described below with reference to FIGS. 8A to 8D and 9A to 9C. A preparation step of preparing a substrate S having a first surface US1 with an outer peripheral portion PP lower than a central portion CP will be described first with reference to FIGS. 8A and 8B. Unless explicitly specified otherwise, a preparation step is not an essential step in the processing method according to the present disclosure, and the substrate S having the first surface US1 with the outer peripheral portion PP lower than the central portion CP may be provided as a target object for which the processing method according to the present disclosure is executed.

In the step shown in FIG. 8A, a semiconductor substrate S′ having an initial first surface US′ with an initial outer peripheral portion PP′ lower than an initial central portion CP′ can be prepared. The central portion CP′ of the substrate S′ can have one or a plurality of trenches TR1. In the filling step shown in FIG. 8B, an insulating film IF can be formed on the surface US′ of the semiconductor substrate S′. The insulating film IF can be formed so as to fill the trench TR1 with an insulator. The insulating film IF can be formed from, for example, silicon oxide, silicon nitride, or silicon oxynitride. With the steps shown in FIGS. 8A and 8B, the substrate S having the first surface US1 with the outer peripheral portion PP lower than the central portion CP is prepared. In this example, the first surface US1 is formed of the insulating film IF placed in the trench TR1 provided in the semiconductor substrate S′ and on the surface of the semiconductor substrate S′.

A film forming step executed before a CMP step will be described below with reference to FIGS. 8C, 8D, 9A, and 9B. A film forming apparatus IAP described above can be applied to a film forming step. In the film forming step, the planarization film PF is formed at least on the outer peripheral portion PP by placing the curable composition CM on the first surface US1 of the substrate S, bringing a superstrate SS into contact with a curable composition CM, and curing the curable composition CM. More specifically, first of all, in the step shown in FIG. 8C, the curable composition CM is placed on the first surface US1 of the substrate S by using the dispenser DP in the film forming apparatus IAP. In this case, the curable composition CM can be placed in a droplet state on the first surface US1 of the substrate S. In the step shown in FIG. 8C, the superstrate SS is brought into contact with the curable composition CM placed on the first surface US1 of the substrate S, and the space between the first surface US1 of the substrate S and the superstrate SS is filled with the curable composition CM.

In the curing step shown in FIG. 9A, a curing unit CU cures the curable composition CM by irradiating the curable composition CM with curing energy CE. In this case, the adjusting unit BM can adjust an irradiation region so as to irradiate a portion (predetermined portion), of the curable composition CM on the first surface US1 of the substrate S, which is located on the outer peripheral portion PP with the curing energy CE. The adjusting unit BM can adjust the intensity distribution of the curing energy CE applied to the curable composition CM. More specifically, the adjusting unit BM irradiates, for example, a portion, of the curable composition CM on the first surface US1 of the substrate S, which extends from an outer edge OE of the substrate S by a predetermined distance D with the curing energy CE. The predetermined distance D may be larger than the width of the outer peripheral portion PP in the diametrical direction of the substrate S. Alternatively, the predetermined distance D may be smaller than the width of the outer peripheral portion PP in the diametrical direction of the substrate S. The predetermined distance D can be determined in accordance with the surface shape of the first surface US1 of the substrate S.

From another viewpoint, an adjusting unit BM can adjust the intensity distribution so as to irradiate a first portion P1, of the curable composition CM on the first surface US1 of the substrate S, which extends from the outer edge OE of the substrate S by a first distance D1 with the curing energy CE having a first intensity. In addition, the adjusting unit BM can adjust the intensity distribution of the curing energy CE so as to irradiate a second portion P2, of the curable composition CM on the first surface US1 of the substrate S, which is placed adjacent to an inside of the first portion P1 with the curing energy CE such that the intensity gradually decreases from the first intensity to the second intensity toward the center of the substrate S. After the curing step, the first portion P1 of the curable composition CM on the first surface US1 of the substrate S is cured, and the second portion P2 gradually decreases in cure degree toward the center of the substrate S. Accordingly, a planarization film PF formed of the cured product of the curable composition CM can be formed on at least the outer peripheral portion PP of the substrate S.

In the step shown in FIG. 9B, the superstrate SS is separated from the planarization film PF and the curable composition CM in an uncured state. Thereafter, a removal step can be executed to remove the curable composition CM left after a curing step. The removal step can include, for example, a wet process of dissolving the curable composition CM. With the above film forming step, the planarization film PF is formed at least on the outer peripheral portion PP of the substrate S.

A CMP step is executed after the film forming step. More specifically, as shown in FIG. 9C, in the CMP step, the unnecessary insulating film IF on the surface of the substrate S (the semiconductor substrate S′) is polished while the insulating film IF (the insulator INS) in the trench TR1 is left. This can obtain an STI structure with the trench TR1 filled with the insulator INS. With this step, a second surface US2 is formed by a surface of the planarization film PF and a surface of the substrate S (the semiconductor substrate S′). The second surface US2 is a surface flatter than the first surface US1.

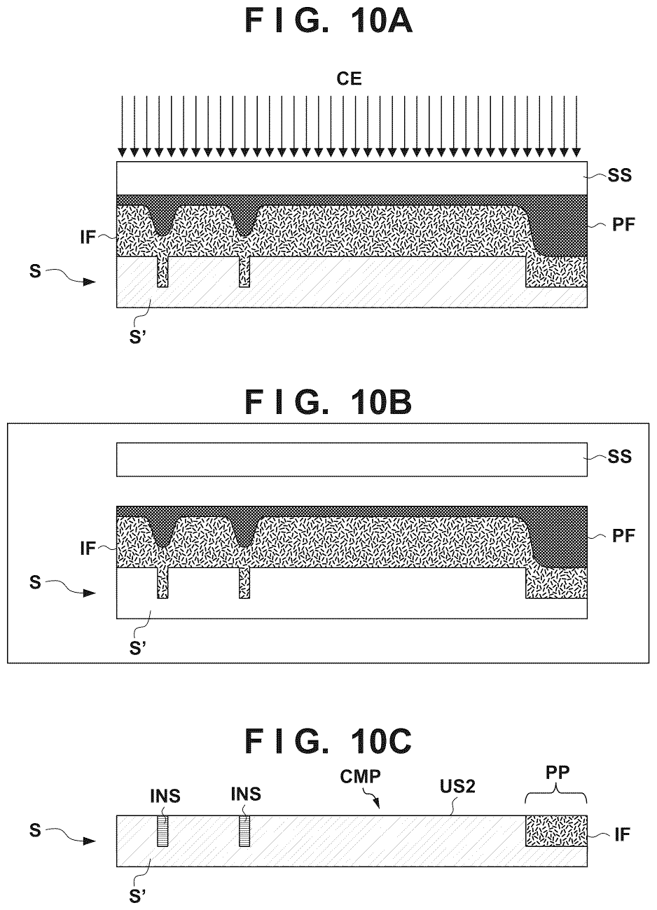

A processing method according to the fifth embodiment will be exemplarily described next with reference to FIGS. 8A to 8D and 10A to 10C. The fifth embodiment is a modification of the fourth embodiment. In a film forming step according to the fifth embodiment, a planarization film PF is formed on a central portion CP and an outer peripheral portion PP of a substrate S. From another viewpoint, an irradiation region of curing energy with respect to a curable composition CM in the fifth embodiment differs from that in the fourth embodiment in that curing energy CE can be applied to the curable composition CM on the central portion CP and the outer peripheral portion PP of the substrate S.

The steps shown in FIGS. 8A to 8D in the fifth embodiment may be the same as those in the fourth embodiment. In the fifth embodiment, after the step shown in FIG. 8D, in the curing step shown in FIG. 10A, a curing unit CU irradiates the curable composition CM on the central portion CP and the outer peripheral portion PP of the substrate S with the curing energy CE to cure the curable composition CM. In other words, in the fifth embodiment, in the curing step shown in FIG. 10A, the curing unit CU cures the entire curable composition CM by irradiating the entire curable composition CM on the substrate S with the curing energy CE. This changes the entire curable composition CM on the substrate S into the planarization film PF.

In the step shown in FIG. 10B, a superstrate SS is separated from the planarization film PF. This forms a second surface US2 using the planarization film PF. With the above film forming step, the planarization film PF is formed on both the central portion CP and the outer peripheral portion PP of the substrate S.

A CMP step is executed after the film forming step. More specifically, as shown in FIG. 10C, in the CMP step, an unnecessary insulating film IF on the surface of the substrate S (a semiconductor substrate S′) is polished while the insulating film IF (an insulator INS) in a trench TR1 is left. This can obtain an STI structure with the trench TR1 filled with the insulator INS. With this step, the second surface US2 is formed by a surface of the planarization film PF and a surface of the substrate S. The second surface US2 is a surface flatter than a first surface US1.

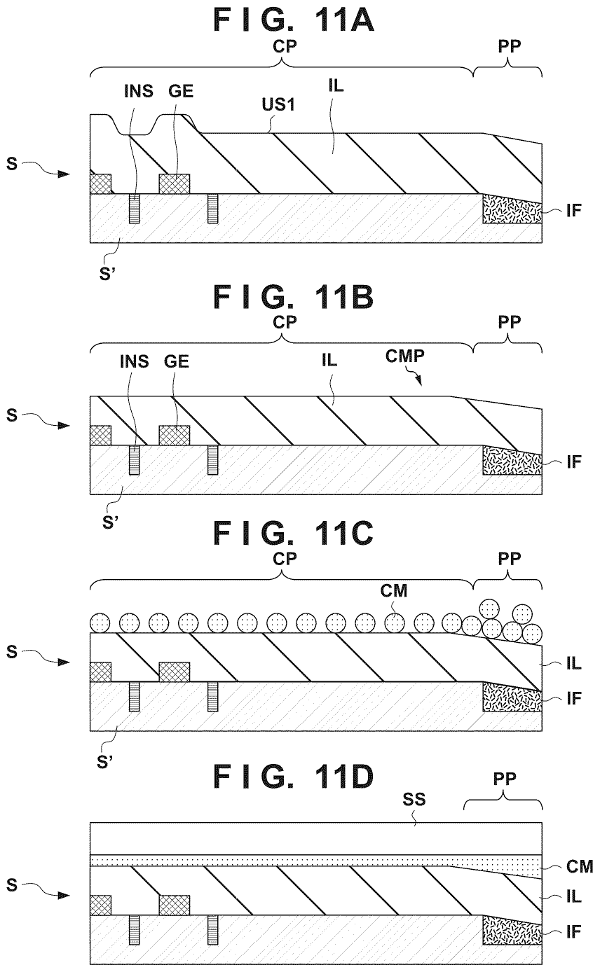

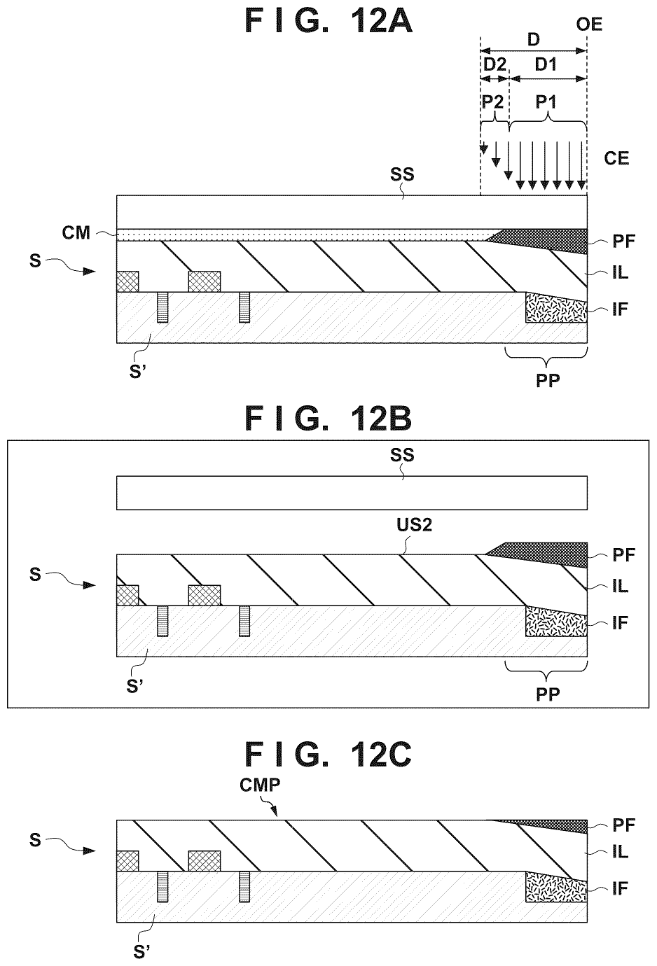

A processing method according to the sixth embodiment will be exemplarily described below with reference to FIGS. 11A to 11D and 12A to 12C. A substrate S having a first surface US1 with an outer peripheral portion PP lower than a central portion CP will be described first with reference to FIG. 11A. The substrate S can be a substrate having undergone the processing method according to any one of the first to fifth embodiments. The substrate S can have a gate electrode GE placed on a gate oxide film (not shown) on a semiconductor substrate S′. The substrate S can have an interlayer dielectric film IL on the semiconductor substrate S′. The substrate S may have one or a plurality of interlayer dielectric films between the semiconductor substrate S′ and the interlayer dielectric film IL.

A film forming step and a CMP step will be described below. In the sixth embodiment, the CMP step is executed before the film forming step. FIG. 11B schematically shows the CMP step. In the CMP step, the interlayer dielectric film IL is polished. In the CMP step, the surface of the interlayer dielectric film IL at the central portion CP of the substrate S can be properly planarized. However, the surface of the interlayer dielectric film IL at the outer peripheral portion PP of the substrate S cannot be planarized, and an inclined surface that is inclined toward an outer edge of the substrate S can be formed. If a subsequent stacking step proceeds in this state, the start position of the inclination of a layer forming the outermost surface moves to the inward of the substrate S. This can cause a problem in a photolithography step (patterning step). For this reason, in the sixth embodiment, a film forming step can be executed after a CMP step.

A film forming step executed after a CMP step will be described below with reference to FIGS. 11C, 11D, 12A, 12B, and 12C. A film forming apparatus IAP described above can be applied to the film forming step. In the film forming step, a planarization film PF is formed on at least the outer peripheral portion PP by placing a curable composition CM on the surface of the substrate S after the CMP step, bringing a superstrate SS into contact with the curable composition CM, and curing the curable composition CM. More specifically, first of all, in the step shown in FIG. 11C, the curable composition CM can be placed on the surface of the substrate S in the film forming apparatus IAP by using a dispenser DP. In this case, the curable composition CM can be placed in a droplet state on the surface of the substrate S. In the step shown in FIG. 11D, the superstrate SS is brought into contact with the curable composition CM placed on the surface of the substrate S, and the space between the surface of the substrate S and the superstrate SS is filled with the curable composition CM.

In the curing step shown in FIG. 12A, a curing unit CU cures the curable composition CM by irradiating the curable composition CM with curing energy CE. In this case, an adjusting unit BM can adjust an irradiation region so as to irradiate a portion (predetermined portion), of the curable composition CM on the surface of the substrate S, which is located on the outer peripheral portion PP with the curing energy CE. The adjusting unit BM can adjust the intensity distribution of the curing energy CE applied to the curable composition CM. More specifically, the adjusting unit BM irradiates a portion, of the curable composition CM on the surface of the substrate S, which extends from an outer edge OE of the substrate S by a predetermined distance D with the curing energy CE. The predetermined distance D may be larger than the width of the outer peripheral portion PP in the diametrical direction of the substrate S. Alternatively, the predetermined distance D may be smaller than the width of the outer peripheral portion PP in the diametrical direction of the substrate S. The predetermined distance D can be determined in accordance with the surface shape of the substrate S.

From another viewpoint, the adjusting unit BM can adjust the intensity distribution so as to irradiate a first portion P1, of the curable composition CM on the surface of the substrate S, which extends from the outer edge OE of the substrate S by a first distance D1 with the curing energy CE having the first intensity. In addition, the adjusting unit BM can adjust the intensity distribution of the curing energy CE so as to irradiate a second portion P2, of the curable composition CM on the surface of the substrate S, which is placed adjacent to an inside of the first portion P1 with the curing energy CE such that the intensity gradually decreases from the first intensity to the second intensity toward the center of the substrate S. After the curing step, the first portion P1 of the curable composition CM on the surface of the substrate S is cured, and the second portion P2 gradually decreases in cure degree toward the center of the substrate S. Accordingly, a planarization film PF formed of the cured product of the curable composition CM can be formed on at least the outer peripheral portion PP of the substrate S.

In the step shown in FIG. 12B, the superstrate SS is separated from the planarization film PF and the curable composition CM in an uncured state. Thereafter, a removal step can be executed to remove the curable composition CM left after a curing step. The removal step can include, for example, a wet process of dissolving the curable composition CM. With the above film forming step, the planarization film PF is formed at least on the outer peripheral portion PP of the substrate S. With this step, a second surface US2 is formed by the planarization film PF and the exposed portion of the interlayer dielectric film IL. The second surface US2 is a surface flatter than the first surface US1.

Subsequently, as shown in FIG. 12C, the second CMP step may be executed. This can obtain a new surface flatter than the second surface US2. A resist pattern can be formed on the surface of the substrate S in a lithography step. The resist pattern can have, for example, an opening for the formation of a contact hole.

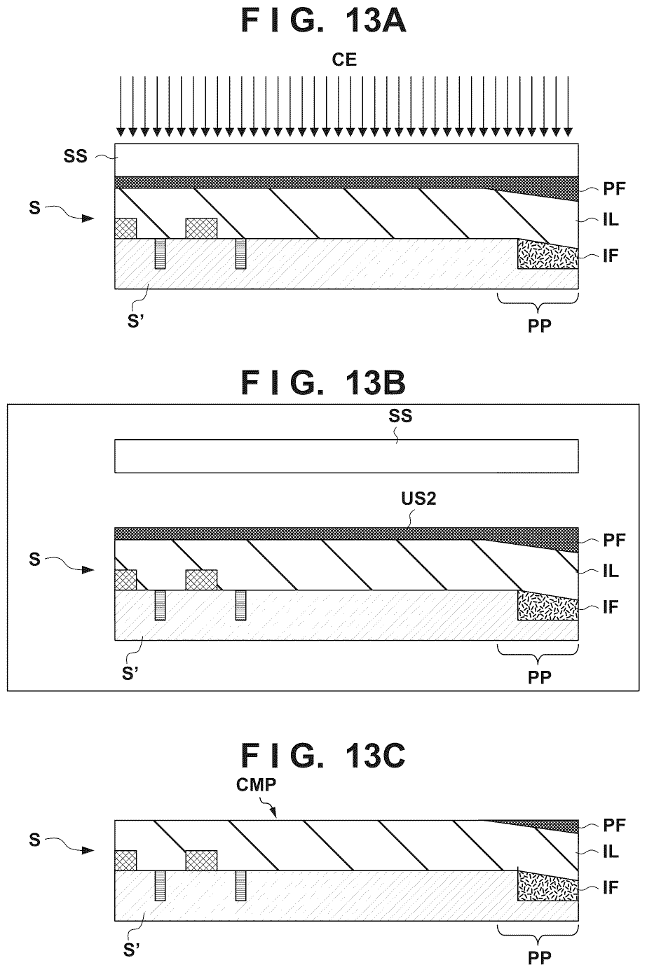

A processing method according to the seventh embodiment will be exemplarily described with reference to FIGS. 11A to 11D and 13A to 13C. The seventh embodiment is a modification of the sixth embodiment. In a film forming step according to the seventh embodiment, a planarization film PF is formed on a central portion CP and an outer peripheral portion PP of a substrate S. From another viewpoint, an irradiation region of curing energy with respect to a curable composition CM in the seventh embodiment differs from that in the sixth embodiment in that curing energy CE can be applied to the curable composition CM on the central portion CP and the outer peripheral portion PP of the substrate S.

The steps shown in FIGS. 11A to 11D in the seventh embodiment may be the same as those in the sixth embodiment. In the seventh embodiment, after the step shown in FIG. 11D, in the curing step shown in FIG. 13A, a curing unit CU irradiates the curable composition CM on the central portion CP and the outer peripheral portion PP of the substrate S with the curing energy CE to cure the curable composition CM. In other words, in the seventh embodiment, in the curing step shown in FIG. 13A, the curing unit CU cures the entire curable composition CM by irradiating the entire curable composition CM on the substrate S with the curing energy CE. This changes the entire curable composition CM on the substrate S into the planarization film PF.

In the step shown in FIG. 13B, a superstrate SS is separated from the planarization film PF. This forms a second surface US2 using the planarization film PF. With the above film forming step, the planarization film PF is formed on both the central portion CP and the outer peripheral portion PP of the substrate S.

The second CMP step may be executed after the above film forming step. This can obtain a new surface flatter than a second surface US2. A resist pattern can be formed on the surface of the substrate S in a lithography step. The resist pattern can have, for example, an opening for the formation of a contact hole.

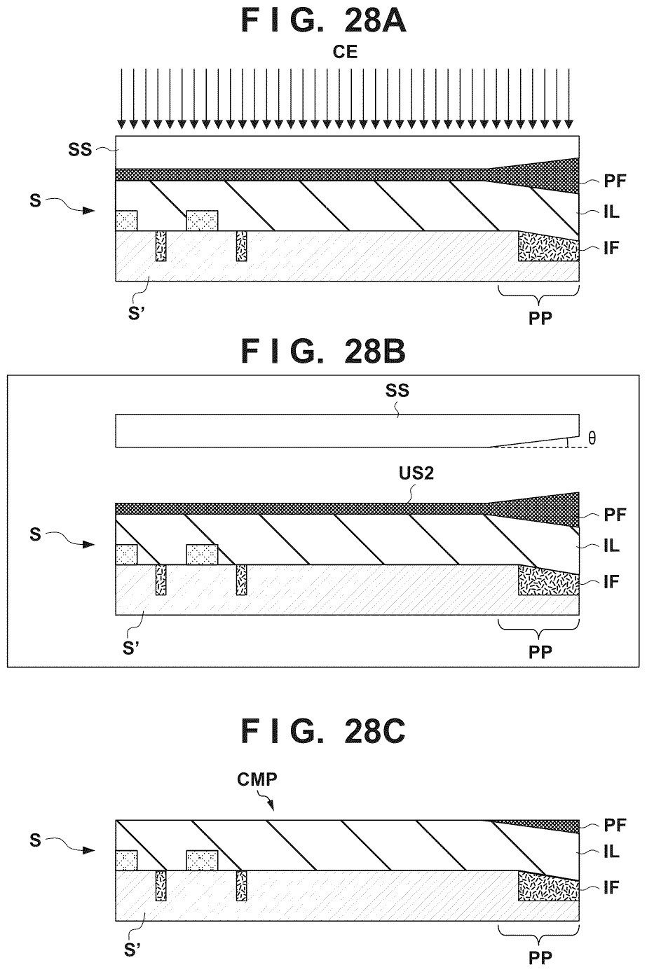

Note that the superstrate SS need not always be flat. For example, as shown in FIGS. 28A to 28C, the superstrate SS may have a shape having an inclination away from the substrate S toward an outer edge of the substrate S. An angle θ of this inclination can fall within the range of 1° to 10° with respect to a plane to which the central portion of the superstrate SS belongs. In this case, the curable composition CM can be placed more (thicker) at a position where it overlaps the outer peripheral portion PP than a position where it overlaps the central portion of the substrate S. The planarization film PF is formed thicker at the position where it overlaps the outer peripheral portion PP than the position where it overlaps the central portion of the substrate S by irradiating the curable composition CM with the curing energy CE. In the subsequent CMP step, the planarization film PF is sometimes scraped more at the position where it overlaps the outer peripheral portion PP than at the position where it overlaps the central portion of the substrate S. In such a case, as shown in FIG. 28C, in the CMP step, the planarization film PF is scraped more at the position where it overlaps the outer peripheral portion PP than at the position where it overlaps the central portion of the substrate S, thereby obtaining a structure with higher flatness. In this manner, making the superstrate SS have a tapered shape can improve the flatness of the substrate S after the CMP step.

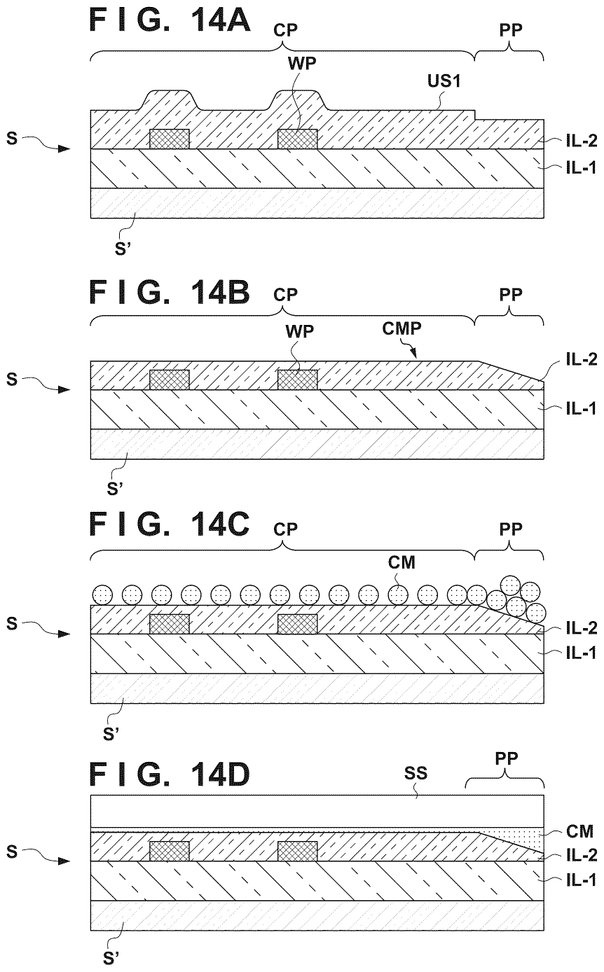

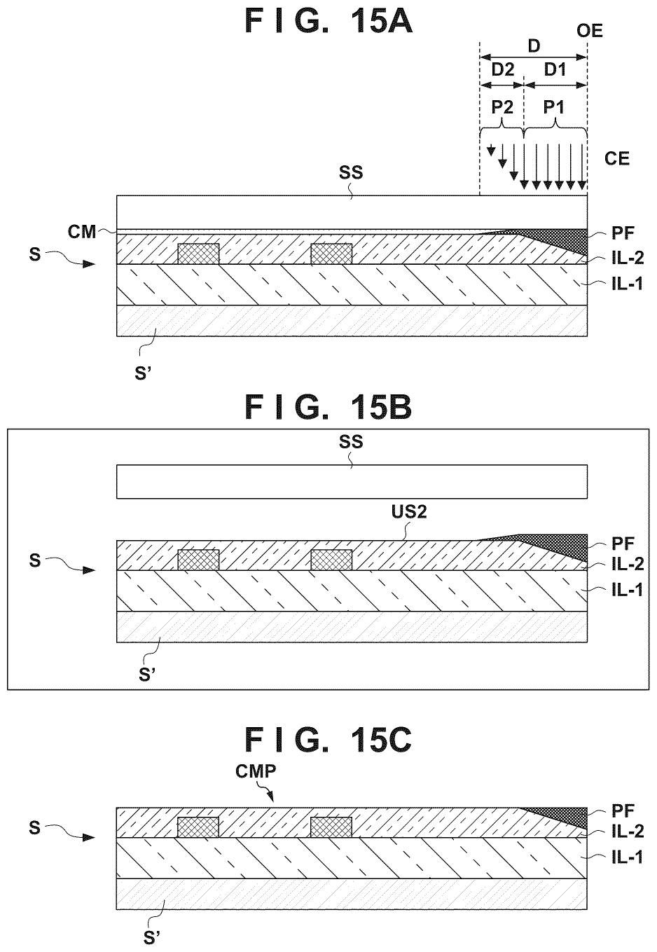

A processing method according to the eighth embodiment will be exemplarily described below with reference to FIGS. 14A to 14D and 15A to 15C. A substrate S having a first surface US1 with an outer peripheral portion PP lower than a central portion CP will be described first with reference to FIG. 14A. The substrate S can be a substrate having undergone the processing method according to any one of the first to fifth embodiments. The substrate S can have a gate electrode (not shown) placed on a gate oxide film (not shown) on a semiconductor substrate S′. The substrate S can have a plurality of interlayer dielectric films IL-1 and IL-2 on the substrate S or the semiconductor substrate S′. The substrate S may have one or more other interlayer dielectric films between the semiconductor substrate S′ and the interlayer dielectric film IL-1. In addition, the substrate S can have a wiring pattern WP, a contact plug, and a via plug between the substrate S and a plurality of interlayer dielectric films. In the example shown in FIGS. 14A to 14D, the first surface US1 of the substrate S has unevenness due to the presence of the wiring pattern WP.

A film forming step and a CMP step will be described below. In the eighth embodiment, the CMP step is executed before the film forming step. FIG. 14B schematically shows the CMP step. In the CMP step, the interlayer dielectric film IL-2 is polished. In the CMP step, at the central portion CP of the substrate S, the surface of the interlayer dielectric film IL-2 can be properly planarized, whereas at the outer peripheral portion PP of the substrate S, the surface of the interlayer dielectric film IL-2 is not planarized, and an inclined surface that is inclined toward an outer edge of the substrate S can be formed. In this state, as a subsequent stacking step proceeds, the start position of the inclination on the layer forming the outermost surface gradually moves to the inward of the substrate S. This can cause a problem in a lithography step (patterning step). For this reason, in the eighth embodiment, a film forming step can be executed after a CMP step.

A film forming step executed after a CMP step will be described below with reference to FIGS. 14C, 14D, 15A, and 15B. A film forming apparatus IAP described above can be applied to the film forming step. In the film forming step, the planarization film PF is formed on at least the outer peripheral portion PP by placing a curable composition CM on the surface of the substrate S after the CMP step, bringing a superstrate SS into contact with the curable composition CM, and curing the curable composition CM. More specifically, first of all, in the step shown in FIG. 14C, the curable composition CM can be placed on the surface of the substrate S in the film forming apparatus IAP by using a dispenser DP. In this case, the curable composition CM can be placed in a droplet state on the surface of the substrate S. In the step shown in FIG. 14D, the superstrate SS is brought into contact with the curable composition CM placed on the surface of the substrate S, and the space between the surface of the substrate S and the superstrate SS is filled with the curable composition CM.

In the curing step shown in FIG. 15A, a curing unit CU cures the curable composition CM by irradiating the curable composition CM with curing energy CE. In this case, an adjusting unit BM can adjust an irradiation region so as to irradiate a portion (predetermined portion), of the curable composition CM on the surface of the substrate S, which is located on the outer peripheral portion PP with the curing energy CE. The adjusting unit BM can adjust the intensity distribution of the curing energy CE applied to the curable composition CM. More specifically, the adjusting unit BM irradiates a portion, of the curable composition CM on the surface of the substrate S, which extends from an outer edge OE of the substrate S by a predetermined distance D with the curing energy CE. The predetermined distance D may be larger than the width of the outer peripheral portion PP in the diametrical direction of the substrate S. Alternatively, the predetermined distance D may be smaller than the width of the outer peripheral portion PP in the diametrical direction of the substrate S. The predetermined distance D can be determined in accordance with the surface shape of the substrate S.

From another viewpoint, the adjusting unit BM can adjust the intensity distribution so as to irradiate a first portion P1, of the curable composition CM on the surface of the substrate S, which extends from the outer edge OE of the substrate S by a first distance D1 with the curing energy CE having the first intensity. In addition, the adjusting unit BM can adjust the intensity distribution of the curing energy CE so as to irradiate a second portion P2, of the curable composition CM on the surface of the substrate S, which is placed adjacent to an inside of the first portion P1 with the curing energy CE such that the intensity gradually decreases from the first intensity to the second intensity toward the center of the substrate S. After the curing step, the first portion P1 of the curable composition CM on the surface of the substrate S is cured, and the second portion P2 gradually decreases in cure degree toward the center of the substrate S. Accordingly, a planarization film PF formed of the cured product of the curable composition CM can be formed on at least the outer peripheral portion PP of the substrate S.

In the step shown in FIG. 15B, the superstrate SS is separated from the planarization film PF and the curable composition CM in an uncured state. Thereafter, a removal step can be executed to remove the curable composition CM left after a curing step. The removal step can include, for example, a wet process of dissolving the curable composition CM. With the above film forming step, the planarization film PF is formed on at least the outer peripheral portion PP of the substrate S. With this step, a second surface US2 is formed by the planarization film PF and the exposed portion of the interlayer dielectric film IL-2. The second surface US2 is a surface flatter than the first surface US1.

Subsequently, as shown in FIG. 15C, the second CMP step may be executed. This can obtain a new surface flatter than the second surface US2. A resist pattern can be formed on the surface of the substrate S in a lithography step. The resist pattern can have, for example, an opening for the formation of a contact hole. Alternatively, the resist pattern can have an opening for the formation of a trench for embedding a metal pattern in the interlayer dielectric film IL-2.

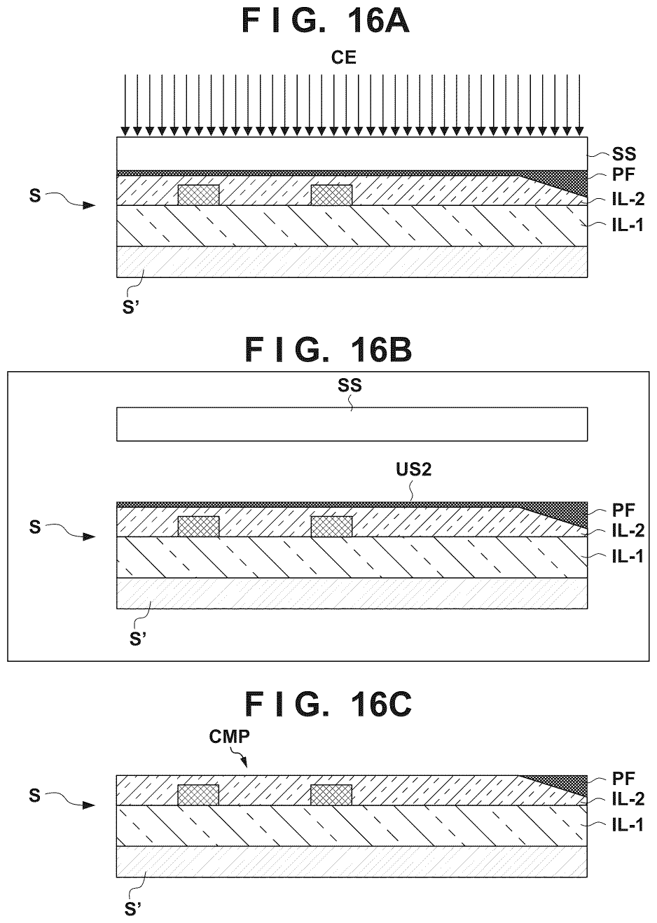

A processing method according to the ninth embodiment will be exemplarily described with reference to FIGS. 14A to 14D and 16A to 16C. The ninth embodiment is a modification of the eighth embodiment. In a film forming step according to the ninth embodiment, a planarization film PF is formed on a central portion CP and an outer peripheral portion PP of a substrate S. From another viewpoint, an irradiation region of curing energy with respect to a curable composition CM in the ninth embodiment differs from that in the eighth embodiment in that curing energy CE can be applied to the curable composition CM on the central portion CP and the outer peripheral portion PP of the substrate S.

The steps shown in FIGS. 14A to 14D in the ninth embodiment may be the same as those in the eighth embodiment. In the ninth embodiment, after the step shown in FIG. 14D, in the curing step shown in FIG. 16A, a curing unit CU irradiates the curable composition CM on the central portion CP and the outer peripheral portion PP of the substrate S with curing energy CE to cure the curable composition CM. In other words, in the ninth embodiment, in the curing step shown in FIG. 16A, the curing unit CU cures the entire curable composition CM by irradiating the entire curable composition CM on the substrate S with the curing energy CE. This changes the entire curable composition CM on the substrate S into the planarization film PF.

In the step shown in FIG. 16B, a superstrate SS is separated from the planarization film PF. This forms a second surface US2 using the planarization film PF. With the above film forming step, the planarization film PF is formed on both the central portion CP and the outer peripheral portion PP of the substrate S.

The second CMP step may be executed after the above film forming step. This can obtain a new surface flatter than the second surface US2. A resist pattern can be formed on the surface of the substrate S in a lithography step. The resist pattern can have, for example, an opening for the formation of a contact hole.

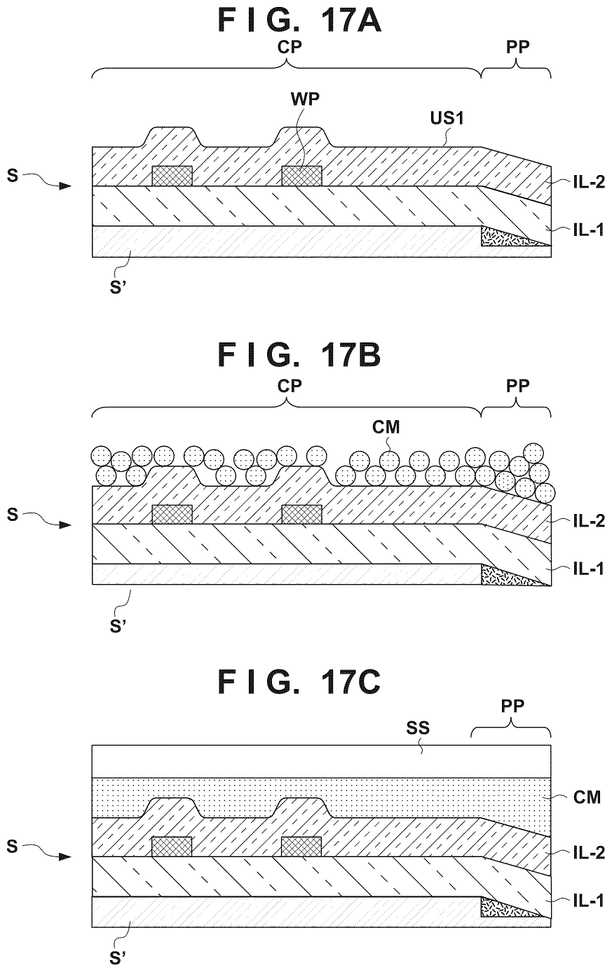

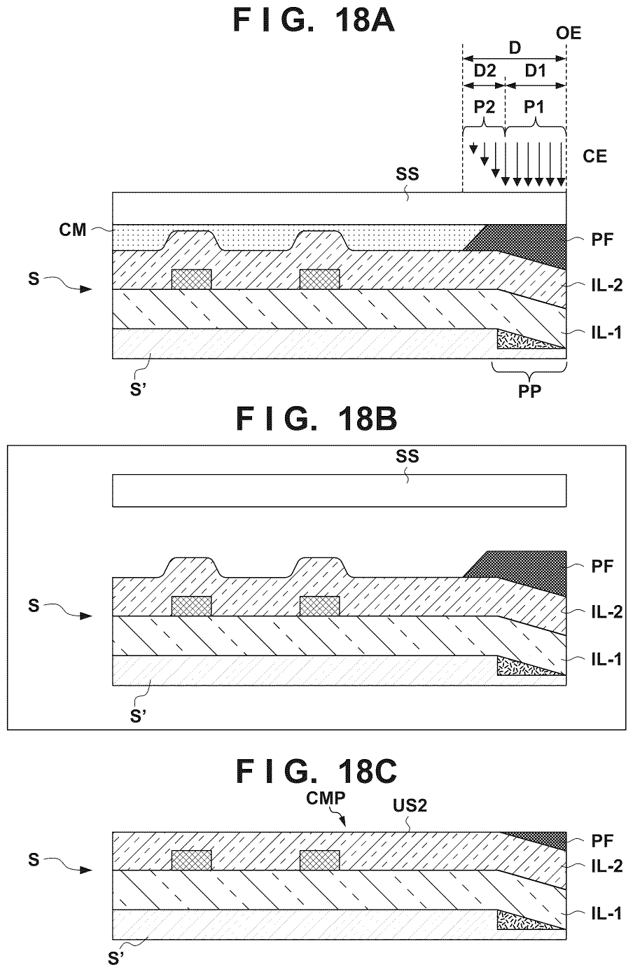

A processing method according to the 10th embodiment will be exemplarily described below with reference to FIGS. 17A to 17C and 18A to 18C. A substrate S having a first surface US1 with an outer peripheral portion PP lower than a central portion CP will be described first with reference to FIG. 17A. The substrate S can be a substrate having undergone the processing method according to any one of the first to fifth embodiments. The substrate S can have a gate electrode (not shown) placed on a gate oxide film (not shown) on a semiconductor substrate S'. The substrate S can have a plurality of interlayer dielectric films IL-1 and IL-2 on the substrate S or the semiconductor substrate S'. The substrate S may have a plurality of other interlayer dielectric films between the semiconductor substrate S and the interlayer dielectric film IL-1. In addition, the substrate S can have a wiring pattern WP, a contact plug, and a via plug between the substrate S and a plurality of interlayer dielectric films. In the example shown in FIGS. 17A to 17C, the first surface US1 of the substrate S has unevenness due to the presence of the wiring pattern WP. In addition, the outer peripheral portion PP can have an inclination.

A film forming step and a CMP step will be described below. In the 10th embodiment, the CMP step is executed after the film forming step. A film forming step executed before a CMP step will be described below with reference to FIGS. 17B, 17C, 18A, and 18B. A film forming apparatus IAP described above can be applied to the film forming step. In the film forming step, a planarization film PF is formed at least on the outer peripheral portion PP by placing a curable composition CM on the first surface US1 of the substrate S, bringing a superstrate SS into contact with the curable composition CM, and curing the curable composition CM. More specifically, first of all, in the step shown in FIG. 17B, the curable composition CM can be placed on the first surface US1 of the substrate S by using a dispenser DP in the film forming apparatus IAP. In this case, the curable composition CM can be placed in a droplet state on the first surface US1 of the substrate S. In the step shown in FIG. 17C, the superstrate SS is brought into contact with the curable composition CM placed on the first surface US1 of the substrate S, and the space between the first surface US1 of the substrate S and the superstrate SS is filled with the curable composition CM.

In the curing step shown in FIG. 18A, a curing unit CU cures the curable composition CM by irradiating the curable composition CM with curing energy CE. In this case, an adjusting unit BM can adjust an irradiation region so as to irradiate a portion (predetermined portion), of the curable composition CM on the first surface US1 of the substrate S, which is located on the outer peripheral portion PP with the curing energy CE. The adjusting unit BM can adjust the intensity distribution of the curing energy CE applied to the curable composition CM. More specifically, the adjusting unit BM irradiates, for example, a portion, of the curable composition CM on the first surface US1 of the substrate S, which extends from an outer edge OE of the substrate S by a predetermined distance D with the curing energy CE. The predetermined distance D may be larger than the width of the outer peripheral portion PP in the diametrical direction of the substrate S. Alternatively, the predetermined distance D may be smaller than the width of the outer peripheral portion PP in the diametrical direction of the substrate S. The predetermined distance D can be determined in accordance with the surface shape of the first surface US1 of the substrate S.

From another viewpoint, the adjusting unit BM can adjust the intensity distribution so as to irradiate a first portion P1, of the curable composition CM on the first surface US1 of the substrate S, which extends from the outer edge OE of the substrate S by a first distance D1 with the curing energy CE having the first intensity. In addition, the adjusting unit BM can adjust the intensity distribution of the curing energy CE so as to irradiate a second portion P2, of the curable composition CM on the first surface US1 of the substrate S, which is placed adjacent to an inside of the first portion P1 with the curing energy CE such that the intensity gradually decreases from the first intensity to the second intensity toward the center of the substrate S. After the curing step, the first portion P1 of the curable composition CM on the first surface US1 of the substrate S is cured, and the second portion P2 gradually decreases in cure degree toward the center of the substrate S. Accordingly, a planarization film PF formed of the cured product of the curable composition CM can be formed on at least the outer peripheral portion PP of the substrate S.

In the step shown in FIG. 18B, the superstrate SS is separated from the planarization film PF and the curable composition CM in an uncured state. Thereafter, a removal step can be executed to remove the curable composition CM left after a curing step. The removal step can include, for example, a wet process of dissolving the curable composition CM. The removal step is executed to expose the interlayer dielectric film IL-2. With the above film forming step, the planarization film PF is formed at least on the outer peripheral portion PP of the substrate S.

As shown in FIG. 18C, a CMP step is executed to planarize the surface formed of the interlayer dielectric film IL-2 and the planarization film PF. The second surface US2 is formed of the surfaces of the interlayer dielectric film IL-2 and the planarization film PF. The second surface US2 is a surface flatter than the first surface US1.

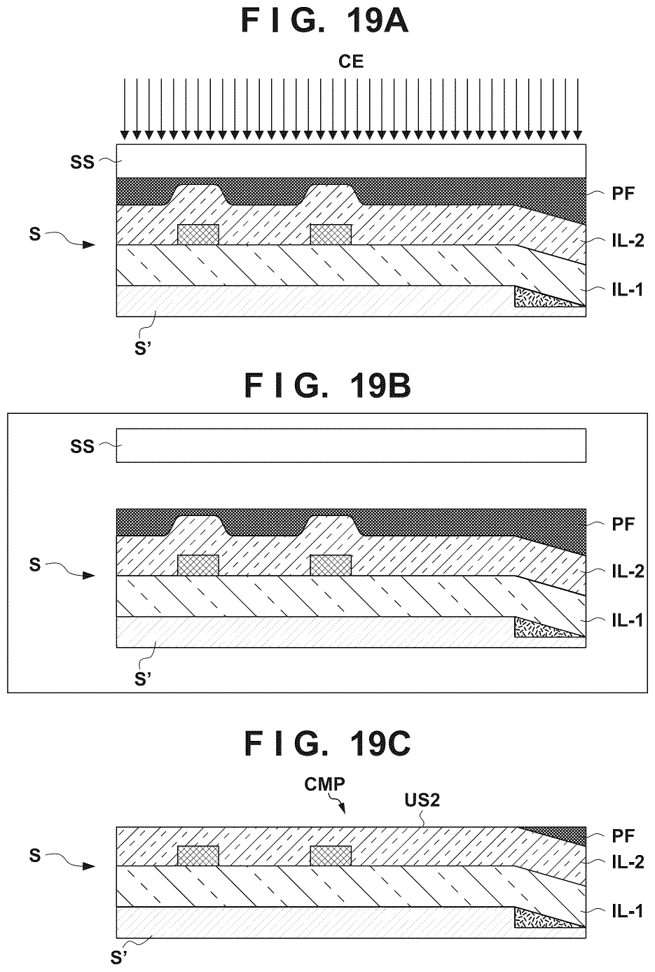

A processing method according to the 11th embodiment will be exemplarily described with reference to FIGS. 17A to 17C and 19A to 19C. The 11th embodiment is a modification of the 10th embodiment. In a film forming step according to the 11th embodiment, a planarization film PF is formed on a central portion CP and an outer peripheral portion PP of a substrate S. From another viewpoint, an irradiation region of curing energy with respect to a curable composition CM in the 11th embodiment differs from that in the fourth embodiment in that curing energy CE can be applied to the curable composition CM on the central portion CP and the outer peripheral portion PP of the substrate S.

The steps shown in FIGS. 17A to 17C in the 11th embodiment may be the same as those in the 10th embodiment. In the 11th embodiment, after the step shown in FIG. 17C, in the curing step shown in FIG. 19A, a curing unit CU irradiates the curable composition CM on the central portion CP and the outer peripheral portion PP of the substrate S with curing energy CE to cure the curable composition CM. In other words, in the 11th embodiment, in the curing step shown in FIG. 19A, the curing unit CU cures the entire curable composition CM by irradiating the entire curable composition CM on the substrate S with the curing energy CE. This changes the entire curable composition CM on the substrate S into the planarization film PF. In the step shown in FIG. 19B, a superstrate SS is separated from the planarization film PF. With the above film forming step, the planarization film PF is formed on both the central portion CP and the outer peripheral portion PP of the substrate S.

A CMP step is executed after the above film forming step. More specifically, as shown in FIG. 19C, in the CMP step, first of all, the planarization film PF is polished. An interlayer dielectric film IL-2 is then polished together with the planarization film PF. This forms a second surface US2 by a surface of the planarization film PF and a surface of the interlayer dielectric film IL-2. The second surface US2 is a surface flatter than a first surface US1.

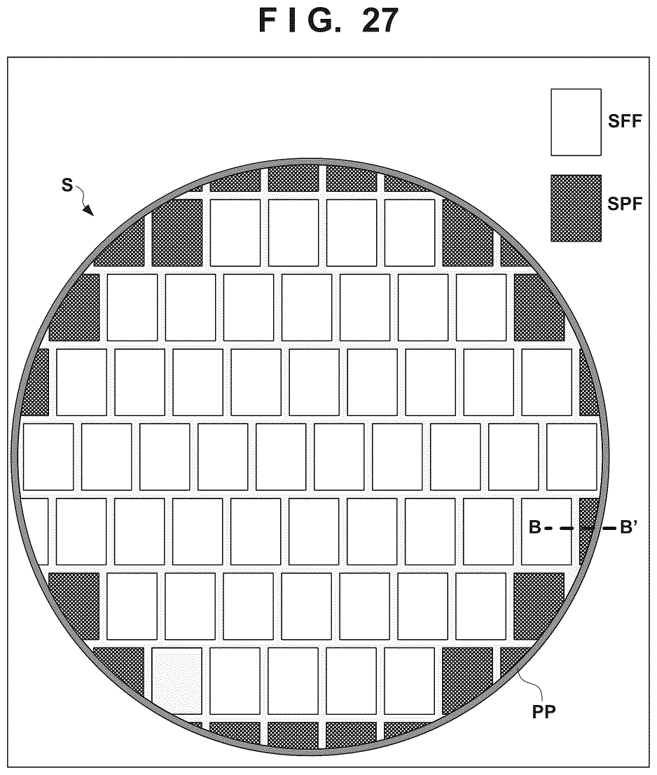

The 12th embodiment will be exemplarily described below. An array of a plurality of shot regions on a substrate S will be exemplarily described with reference to FIG. 27. Rectangles with no pattern represent shot regions called full fields SFF, and rectangles with hatching patterns represent shot regions called partial fields SPF. The full fields SFF are shot regions that entirely fall inside the inner edge of an outer peripheral portion PP. The partial fields SPF are shot regions whose outer edges are defined by the outer peripheral portion PP. In a process in which one shot region includes a plurality of chip regions, chip regions that are not defined by the outer peripheral portion PP can be used for the manufacture of a device (chip) even if they are partial fields. In contrast to this, in a process in which one shot region is formed of one chip region, for example, in a process of manufacturing an image sensor with a full size (full frame), no partial field is used. Any partial field that is not used for the manufacture of a device is called an unused partial field.

In an exposure step in a lithography step, in a case where an unused partial field is not exposed to light, for example, a negative photoresist is used, no resist film is left on the unused partial field through a developing step. Accordingly, in the subsequent etching step, since the entire region of a process target layer in a partial field is etched, the flatness of a surface of the substrate can deteriorate. For this reason, usually, even unused partial field is exposed to light in an exposure step, and a resist pattern can be formed on the unused partial field through a developing step.

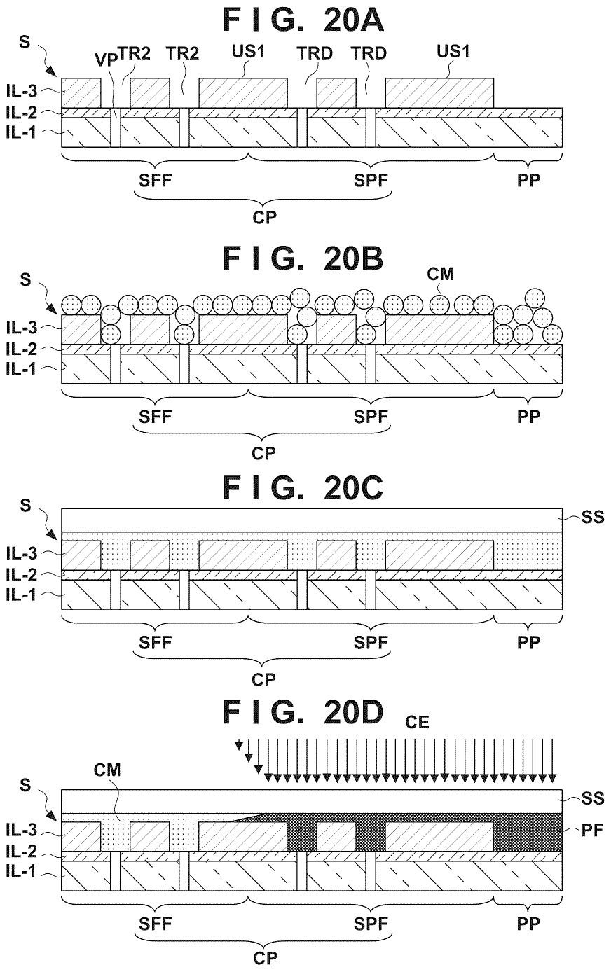

In a damascene process, if a trench formed in the interlayer dielectric film of such a partial field is filled with a metal, a front opening unified pod (FOUP) and post-process devices may be contaminated with the metal. Accordingly, in a damascene process, it is preferable that no metal film is formed on a partial field. FIGS. 20A to 25 referenced below are schematic sectional views taken along line B-B′ in FIG. 27.

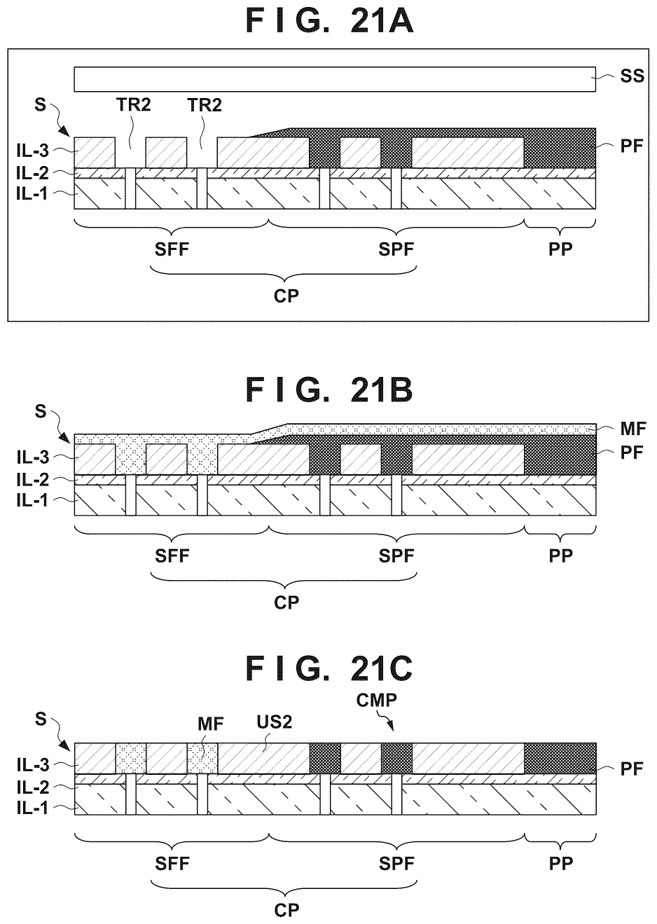

A processing method according to the 12th embodiment will be exemplarily described below with reference to FIGS. 20A to 20D and 21A to 21C. The substrate S having a first surface US1 with the outer peripheral portion PP lower than a central portion CP will be described first with reference to FIG. 20A. The substrate S can be a substrate having undergone the processing method according to any one of the first to fifth embodiments. The substrate S can have a gate electrode (not shown) placed on a gate oxide film (not shown) on a semiconductor substrate (not shown). The substrate S can have a plurality of interlayer dielectric films such as interlayer dielectric films IL-1, IL-2, and IL-3 arranged on the substrate S or the semiconductor substrate. The substrate S may have one or a plurality of other interlayer dielectric films between the semiconductor substrate (not shown) and the interlayer dielectric film IL-1. In this example, the substrate S has the central portion CP and the outer peripheral portion PP. The central portion CP has the full fields SFF and the partial fields SPF. The interlayer dielectric film IL-3 has one or a plurality of trenches TR2 arranged in the full fields SFF. The trench TR2 is used for the formation of a wiring pattern. The interlayer dielectric film IL-3 also has one or a plurality of dummy trenches TRD arranged in the partial fields SPF. The dummy trench TRD can be formed by a lithography step using a reticle (original plate) for the formation of the trench TR2 in the full field SFF. From another viewpoint, the interlayer dielectric film IL-3 can include the dummy trenches TRD arranged in outside regions (the partial fields SPF) on the central portion CP in addition to one or plurality of trenches TR2 arranged in the central portion CP (its full fields SFF). In a single damascene process, the interlayer dielectric films IL-1 and IL-2 can have via plugs VP facing the trenches TR2 in the full fields SFF. In a dual damascene process, the interlayer dielectric films IL-1 and IL-2 can have via holes for the formation of the via plugs VP so as to communicate with the trenches TR2 in the full fields SFF.

A film forming step and a CMP step will be described below. In the 12th embodiment, the CMP step is executed after the film forming step, more specifically, after the film forming step and the metal film forming step. The film forming step will be described first with reference to FIGS. 20B to 20D and 21A. A film forming apparatus IAP described above can be applied to the film forming step. In the film forming step, a curable composition CM is placed on the first surface US1 of the substrate S, a superstrate SS is brought into contact with the curable composition CM, and the curable composition CM is cured. This forms the planarization film PF on at least the partial fields SPF of the central portion CP in addition to the outer peripheral portion PP. More specifically, first of all, in the step shown in FIG. 20B, the curable composition CM can be placed on the first surface US1 of the substrate S by using a dispenser DP in the film forming apparatus IAP. In this case, the curable composition CM can be placed in a droplet state on the first surface US1 of the substrate S. In the step shown in FIG. 20C, the superstrate SS is brought into contact with the curable composition CM placed on the first surface US1 of the substrate S, and the space between the first surface US1 of the substrate S and the superstrate SS is filled with the curable composition CM.

In the curing step shown in FIG. 20D, a curing unit CU cures the curable composition CM by irradiating the curable composition CM with curing energy CE. In this case, an adjusting unit BM can adjust an irradiation region so as to irradiate portions of, the curable composition CM on the first surface US1 of the substrate S, which are located on the partial fields SPF of the outer peripheral portion PP and the central portion CP with curing energy CE.

In the step shown in FIG. 21A, the superstrate SS is separated from the planarization film PF and the curable composition CM in an uncured state. Thereafter, a removal step can be executed to remove the curable composition CM left after a curing step. The removal step can include, for example, a wet process of dissolving the curable composition CM. The removal step is executed to expose the bottom of a trench TR1. With the above film forming step, the planarization film PF is formed on the partial fields SPF of the central portion CP in addition to at least the outer peripheral portion PP of the substrate S.

As shown in FIG. 21B, a metal film MF is then formed on the interlayer dielectric film IL-3 so as to fill the trench TR2 with a metal.

Subsequently, as shown in FIG. 21C, a CMP step is executed to expose the upper surface of the interlayer dielectric film IL-3. The second surface US2 is formed by a surface of the interlayer dielectric film IL-3, a surface of the metal film MF, and a surface of the planarization film PF. The second surface US2 is a surface flatter than the first surface US1. The metal film MF (metal) filling the trench TR2 forms a wiring pattern.

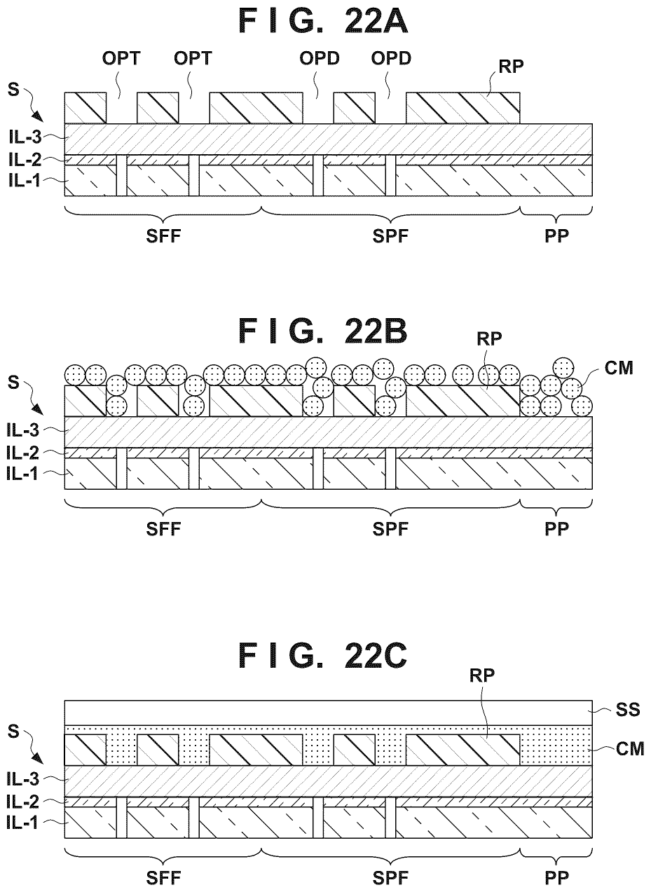

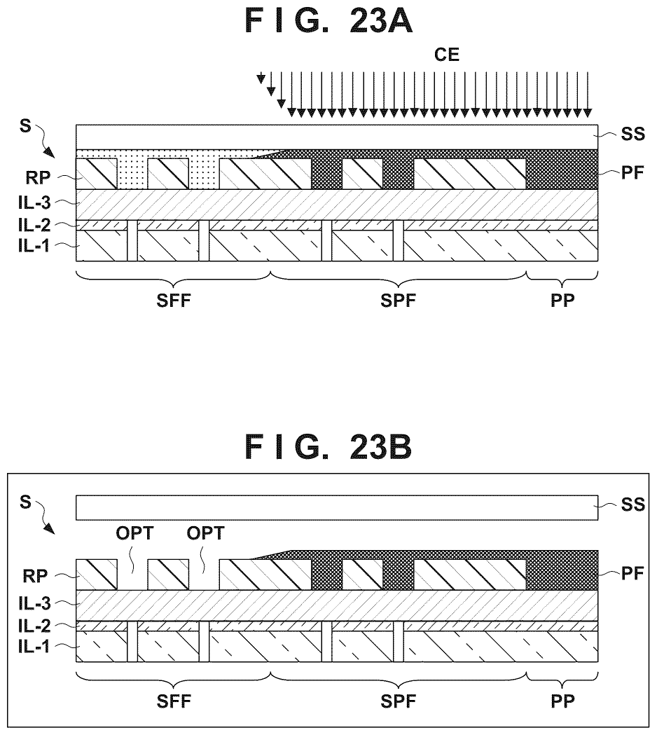

A processing method according to the 13th embodiment will be exemplarily described below with reference to FIGS. 22A to 22C, 23A, and 23B. The 13th embodiment provides a processing method advantageous in forming trenches TR2 in a full field SFF without forming any dummy trench TRD in a partial field SPF.

In the step shown in FIG. 22A, a resist pattern RP can be formed by a lithography step on a substrate S having a plurality of interlayer dielectric films such as interlayer dielectric films IL-1, IL-2, and IL-3 on a semiconductor substrate (not shown). The resist pattern RP can have an opening OPT for the formation of the trench TR2 in the interlayer dielectric film IL-3 and a dummy opening OPD for the formation of the dummy trench TRD.

A film forming step can be executed next as shown in FIGS. 22B, 22C, 23A, and 23B. First of all, in the step shown in FIG. 22B, a curable composition CM can be placed on the resist pattern RP and the exposed portion of the substrate S in a film forming apparatus IAP by using a dispenser DP. In the step shown in FIG. 22C, a superstrate SS is brought into contact with the curable composition CM, and the spaces between the resist pattern RP, the exposed portion of the substrate S, and the superstrate SS are filled with the curable composition CM.

In the curing step shown in FIG. 23A, a curing unit CU cures the curable composition CM by irradiating the curable composition CM with curing energy CE. In this case, an adjusting unit BM can adjust an irradiation region so as to irradiate portions, of the curable composition CM, which are located on the outer peripheral portion PP and the partial field SPF of a central portion CP with the curing energy CE.

In the step shown in FIG. 23B, the superstrate SS is separated from the planarization film PF and the curable composition CM in an uncured state. Thereafter, a removal step can be executed to remove the curable composition CM left after a curing step. The removal step can include, for example, a wet process of dissolving the curable composition CM. The removal step is executed to expose the bottom of the opening OPT. With the above film forming step, the dummy opening OPD and the outer peripheral portion PP of the substrate S are covered by the planarization film PF. Etching the interlayer dielectric film IL-3 through the opening OPT in this state can form the trench TR2 in the full field SFF without forming any dummy trench TRD in the partial field SPF.

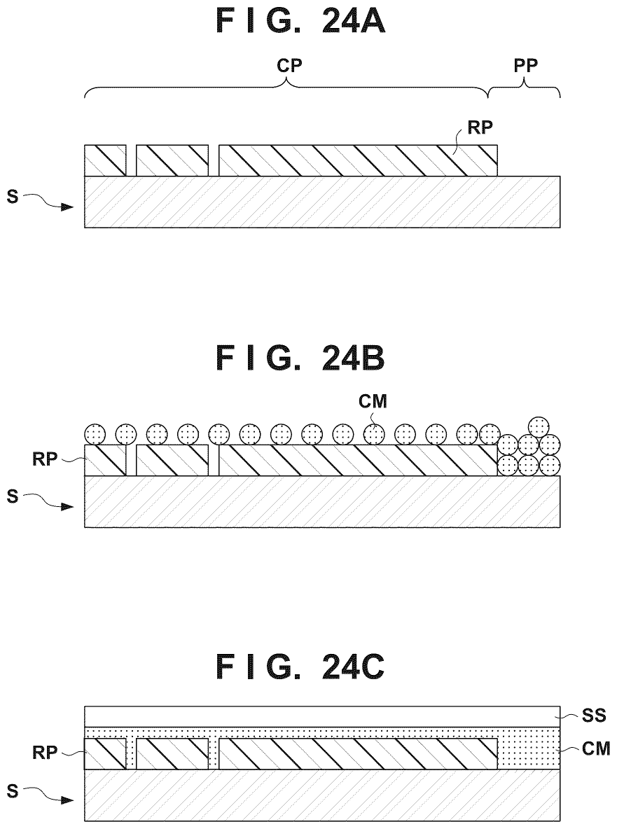

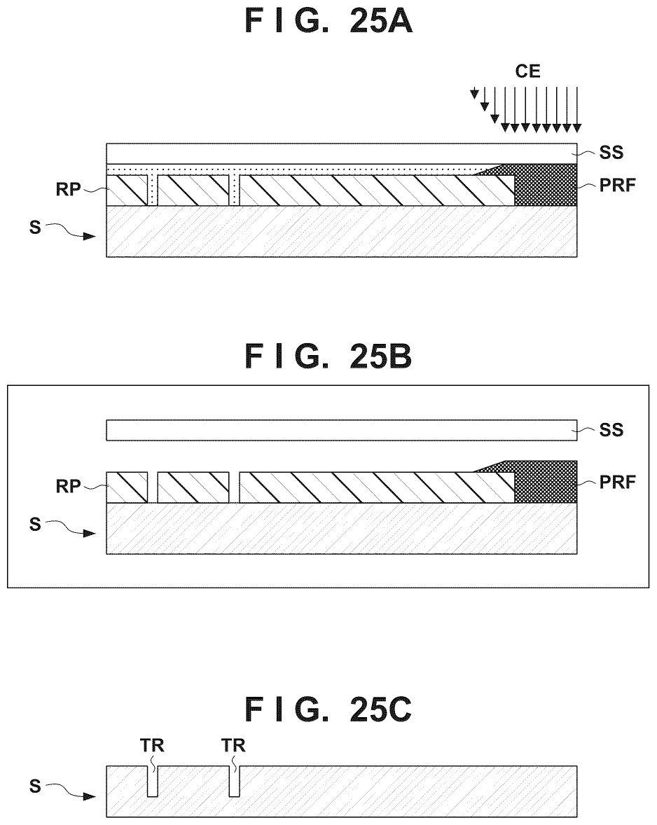

A processing method according to the 14th embodiment will be described below with reference to FIGS. 24A to 24C and 25A to 25C. The 14th embodiment provides a processing method advantageous in forming a resist pattern RP and a protective film protecting an outer peripheral portion PP of a substrate S having undergone an EBR process.

In the step shown in FIG. 24A, the resist pattern RP is formed on the substrate S, and the substrate S having undergone an EBR process is prepared. A film forming step can be executed as shown in FIGS. 24B, 24C, 25A, 25B, and 25C. First of all, in the step shown in FIG. 24B, a curable composition CM can be placed on the resist pattern RP and the exposed portion of the substrate S in a film forming apparatus IAP by using a dispenser DP. In the step shown in FIG. 24C, a superstrate SS is brought into contact with the curable composition CM, and the spaces between the resist pattern RP, the exposed portion of the substrate S, and the superstrate SS are filled with the curable composition CM.

In the curing step shown in FIG. 25A, a curing unit CU cures the curable composition CM by irradiating the curable composition CM with curing energy CE, thereby forming a protective film PRF. In this case, an adjusting unit BM can adjust an irradiation region so as to irradiate the outer peripheral portion PP of the curable composition CM with the curing energy CE.

In the step shown in FIG. 25B, the superstrate SS is separated from the planarization film PRF and the curable composition CM in an uncured state. Thereafter, a removal step can be executed to remove the curable composition CM left after a curing step. The removal step can include, for example, a wet process of dissolving the curable composition CM. With the above film forming step, the protective film PRF that protects the outer peripheral portion PP is formed.

Note that an EBR process is executed to prevent the generation of particles when the resist pattern RP comes into contact with an FOUP or the like. The protective film PRF is formed from a curable composition that is less likely to generate particles than a constituent material of the prospective region.

A semiconductor device manufacturing method will be described below as another embodiment. The semiconductor device manufacturing method can include the processing method according to any one of the first to 14th embodiments or the first processing step of processing a substrate by an arbitrary combination of these methods and the second processing step of obtaining a semiconductor device by further processing the substrate having undergone the first processing step. The second processing step can include, for example, at least one of a dicing step, a sealing step, and a joining step for another substrate. In a case where the first processing step includes a step of forming an STI structure, the second processing step can include a step of forming a transistor, a step of forming an interlayer dielectric film, a step of forming a wiring pattern, and the like.

In each embodiment described above, in the step of irradiating the curable composition CM with the curing energy CE through the superstrate SS, the first gas may be supplied to the outer peripheral portion of the substrate S, and the second gas may be supplied to the central portion of the substrate S. In this case, the oxygen concentration of the first gas is set to be higher than that of the second gas. In a case where the curable composition CM is cured, radicals generated by irradiation with exposure light photopolymerize the curable composition CM to cure it. However, the generated radicals have the property of being trapped by oxygen and hence can suppress the progression of photopolymerization reaction. Supplying the first gas by using this property to the outer peripheral portion of the substrate S can reduce the curing of the curable composition CM leaking outside the superstrate SS. This makes it possible to vaporize the uncured curable composition CM left after the separation of the superstrate SS from the planarization film PF. Accordingly, even if there is the curable composition CM leaking outside the superstrate SS, the curable composition CM can be properly removed by subsequent vaporization. As described in the 14th embodiment in particular, storing the substrate S in an FOUP or the like after sufficient vaporization of the curable composition CM can reduce the contamination of the FOUP or the like.

It is possible to refer to Japanese Patent Laid-Open No. 2024-29829 concerning a method of controlling the progression of the curing of the curable composition CM by using the first and second gases and a specific method of supplying the first and second gases. In addition, as a material used as the curable composition CM, for example, a material described in Japanese Patent Laid-Open No. 2022-188736 can be used as appropriate.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-199201, filed Nov. 14, 2024, which is hereby incorporated by reference herein in its entirety.

What is claimed is:

1. A processing method of processing a substrate having a first surface with an outer peripheral portion lower than a central portion and forming a second surface flatter than the first surface, the method comprising:
forming a planarization film on at least the outer peripheral portion by placing a curable composition on the substrate, bringing a superstrate into contact with the curable composition, and curing the curable composition; and
executing chemical mechanical polishing (CMP) before or after the forming,
wherein the second surface is formed through the forming and the executing the CMP.

2. The method according to claim 1, wherein the forming includes irradiating a portion, of the curable composition on the first surface, which extends from an outer edge of the substrate by a predetermined distance with curing energy.

3. The method according to claim 2, wherein the predetermined distance is larger than a width of the outer peripheral portion in a diametrical direction of the substrate.

4. The method according to claim 2, wherein the forming includes removing a curable composition left after the irradiating.

5. The method according to claim 1, wherein the forming includes irradiating a first portion, of the curable composition on the first surface, which extends from an outer edge of the substrate by a first distance with curing energy having a first intensity and irradiating a second portion placed adjacent to an inside of the first portion with curing energy with an intensity gradually decreasing from the first intensity to a second intensity toward a center of the substrate.

6. The method according to claim 1, wherein the CMP is executed before the forming.

7. The method according to claim 6, wherein the first surface is formed from an insulator.

8. The method according to claim 6, wherein the substrate includes a semiconductor substrate, and
the first surface is formed from an insulator placed in a trench provided in the semiconductor substrate and on a surface of the semiconductor substrate.

9. The method according to claim 6, wherein the substrate includes a semiconductor substrate, and
the first surface is formed from an interlayer dielectric film placed on the semiconductor substrate.

10. The method according to claim 1, wherein in the forming, the planarization film is formed on the central portion and the outer peripheral portion.

11. The method according to claim 10, further comprising executing second CMP after the forming.

12. The method according to claim 1, wherein the CMP is executed after the forming.

13. The method according to claim 12, wherein the substrate includes a semiconductor substrate, and
the first surface is formed from the semiconductor substrate.

14. The method according to claim 12, wherein the substrate includes a semiconductor substrate,
the first surface includes a trench provided in the semiconductor substrate, and
the trench is filled with an insulator after the forming and before the executing the CMP.

15. The method according to claim 12, wherein the substrate includes a semiconductor substrate, and
the first surface is formed from an insulator placed in a trench provided in the semiconductor substrate and on a surface of the semiconductor substrate.

16. The method according to claim 12, wherein the substrate includes a semiconductor substrate, and
the first surface is formed from an interlayer dielectric film placed on the semiconductor substrate.

17. The method according to claim 12, wherein the substrate includes a semiconductor substrate,
the first surface is formed from an interlayer dielectric film placed on the semiconductor substrate,
the interlayer dielectric film includes a trench placed in the central portion, and
a metal film is formed on the interlayer dielectric film so as to fill the trench with a metal after the forming and before the executing the CMP.

18. The method according to claim 17, wherein the interlayer dielectric film includes a dummy trench placed in an outside region on the central portion in addition to the trench, and
in the forming, the planarization film is formed on the dummy trench in addition to the outer peripheral portion.

19. A processing method comprising:
forming a resist pattern on a substrate;
forming a protective film on at least an outer peripheral portion of the substrate by placing a curable composition on the substrate, bringing a superstrate into contact with the curable composition, and curing the curable composition; and
etching the substrate having undergone the forming the protective film.

20. The method according to claim 19, wherein the substrate includes an interlayer dielectric film,
the resist pattern includes an opening for formation of a trench in the interlayer dielectric film, and
in the etching, the trench is formed in the interlayer dielectric film.

21. The method according to claim 20, wherein the resist pattern includes a dummy opening, and
in the forming the protective film, the protective film is formed on the dummy opening in addition to an outer peripheral portion of the substrate.

22. A semiconductor device manufacturing method comprising:
a first step of processing a substrate having a first surface with an outer peripheral portion lower than a central portion; and
a second step of obtaining a semiconductor device by further processing the substrate having undergone the first step,
wherein the first step comprises:
forming a planarization film on at least the outer peripheral portion by placing a curable composition on the substrate, bringing a superstrate into contact with the curable composition, and curing the curable composition; and
executing chemical mechanical polishing (CMP) before or after the forming the planarization film,
wherein a second surface flatter than the first surface is formed through the first step.
